(19) United States
(12) Patent Application Publication
(10) Pub. No.: US 2025/0393355 A1
(43) Pub. Date: Dec. 25, 2025

(54) DISPLAY DEVICE, METHOD OF MANUFACTURING THE SAME, AND DISPLAY SYSTEM

(71) Applicant: Samsung Display Co., LTD., Yongin-si (KR)

(72) Inventor: Moon Won CHANG, Yongin-si (KR)

(73) Assignee: Samsung Display Co., LTD., Yongin-si (KR)

(21) Appl. No.: 19/179,122

(22) Filed: Apr. 15, 2025

(30) Foreign Application Priority Data
Jun. 21, 2024 (KR) 10-2024-0081329
Jul. 5, 2024 (KR) 10-2024-0089061

(51) Int. Cl. H10H 29/37; H10H 29/01; H10H 29/853

(52) U.S. Cl. CPC H10H 29/37; H10H 29/012; H10H 29/0362; H10H 29/853

(57) ABSTRACT

Provided is a display device including: a substrate extending in a first direction and a second direction intersecting the first direction and including a display area and a non-display area around the display area; and a display element layer disposed on the substrate in a third direction intersecting the first and second directions, wherein the display element layer includes a bank disposed on the display area of the substrate and having openings; light emitting elements respectively overlapping the openings and at least partially disposed in the openings; and a dam member disposed in the display area along an edge of the display area, and the light emitting elements have a first height in the third direction, and the dam member has a second height greater than the first height in the third direction.

### CROSS-REFERENCE TO RELATED APPLICATION(S)

This application claims priority to and the benefits of Korean Patent Application No. 10-2024-0081329 under 35 U.S.C. § 119, filed on Jun. 21, 2024, and Korean Patent Application No. 10-2024-0089061 under 35 U.S.C. § 119, filed on Jul. 5, 2024, in the Korean Intellectual Property Office, the entire contents of which are incorporated herein by references.

### BACKGROUND

### 1. Technical Field

This disclosure generally relates to a display device, a method of manufacturing the display device and display system. More particularly, the disclosure relates to a display device with improved reliability and a method of manufacturing the display device.

### 2. Description of the Related Art

Importance of a display device is increasing with development of multimedia. Accordingly, the use of display devices such as liquid crystal display devices, organic light emitting display devices, and inorganic light emitting display devices is increasing. Particularly, research is being actively conducted on micro-LEDs that may realize high luminance and faster response speed compared to conventional LEDs.

The above information disclosed in this Background section is only for enhancement of understanding of the background of the inventive concepts, and, therefore, it may contain information that does not form the prior art that is already known to a person of ordinary skill in the art.

### SUMMARY

Embodiments of this disclosure may provide a display device with improved reliability and a method of manufacturing the same. For example, a display device may improve reliability in a bonding process of a light emitting element by disposing a dam member with a height greater than that of the light emitting element on a substrate.

An embodiment of this disclosure may provide a display device including: a substrate extending in a first direction and a second direction intersecting the first direction and including a display area and a non-display area around the display area; and a display element layer disposed on the substrate in a third direction intersecting the first and second directions, wherein the display element layer includes a bank disposed on the display area of the substrate and having openings; light emitting elements, each of the light emitting elements overlapping the openings and at least partially disposed in the openings; and a dam member disposed in the display area along an edge of the display area, and each of the light emitting elements have a first height in the third direction, and the dam member has a second height greater than the first height in the third direction.

The bank may have a third height in the third direction, and the third height may be less than the second height.

The display element layer may have a fourth height in the third direction, and the fourth height may be less than the second height.

The first height may be a distance between the substrate and an upper surface of a light emitting element, and the second height may be a distance between the substrate and an end of the dam member.

The display element layer may further include anode electrodes which overlap the openings respectively, and the light emitting elements may be disposed on the anode electrodes.

The display device may further include bonding members disposed between the light emitting elements and the anode electrodes, wherein the bonding members may include a Sn—Ag—Cu (SAC) alloy.

The display element layer may further include an overcoat layer disposed in the openings, respectively, and the light emitting elements may be partially buried in the overcoat layer.

The bank may have a third height in the third direction, and the third height may be substantially equal to the second height.

A first portion of the bank may have a third height in the third direction, a second portion of the bank may have a fifth height in the third direction, the third height may be greater than the fifth height, and the third height may be substantially equal to the second height.

Another embodiment of this disclosure may provide a method of manufacturing a display device, including: forming, on a display area of a substrate extending in a first direction and a second direction intersecting the first direction, a bank in a third direction intersecting the first and second directions, the bank having openings; forming a dam member, the dam member disposed along an edge of the display area; aligning light emitting elements disposed on a surface of a carrier substrate, and the openings to face each other; moving the carrier substrate toward the substrate and disposing the light emitting elements at least partially in the openings; and separating the carrier substrate from the light emitting elements.

The dam member may be formed on the substrate in the third direction in the display area.

Each of the light emitting elements may have a first height in the third direction, and the dam member may have a second height greater than the first height in the third direction.

The bank may have a third height in the third direction, and the third height may be less than or substantially equal to the second height.

A first portion of the bank may have a third height in the third direction, a second portion of the bank may have a fifth height in the third direction, the third height may be greater than the fifth height, and the third height may be substantially equal to the second height.

The disposing of the light emitting elements at least partially in the openings may further include applying heat or pressure to another surface opposite to the surface of the carrier substrate.

The carrier substrate may include an adhesive layer disposed on the one surface of the carrier substrate, the adhesive layer may be disposed between the carrier substrate and the light emitting elements, and may expand by the heat, and Expansion of the adhesive layer may be blocked in a portion of the adhesive layer by the dam member.

The dam member may be formed on a surface of a carrier substrate on which light emitting elements are disposed.

In the separating of the carrier substrate from the light emitting elements, the dam member may be separated from the substrate together with the carrier substrate.

Each of the light emitting elements may have a first length in the third direction, and the dam member may have a second length longer than the first length in the third direction.

A display system may include a processor to provide input image data and a display device to display an image based on the input image data, wherein the display device includes a substrate extending in a first direction and a second direction intersecting the first direction and including a display area and a non-display area around the display area and a display element layer disposed on the substrate in a third direction intersecting the first and second directions, wherein the display element layer includes a bank disposed on the display area of the substrate and having openings light emitting elements, each of the light emitting elements overlapping the openings and at least partially disposed in the openings and a dam member disposed in the display area along an edge of the display area, each of the light emitting elements has a first height in the third direction, and the dam member has a second height greater than the first height in the third direction.

### BRIEF DESCRIPTION OF THE DRAWINGS

FIG. 1 illustrates a schematic block diagram of a display device according to an embodiment.

FIG. 2 illustrates a schematic block diagram of one of sub-pixels of FIG. 1 according to an embodiment.

FIG. 3 illustrates a schematic top plan view of a display panel of FIG. 1 according to an embodiment.

FIG. 4 illustrates a schematic cross-sectional view of a display panel of FIG. 3 according to an embodiment.

FIG. 5 illustrates a schematic cross-sectional view of a display panel of FIG. 3 according to another embodiment.

FIG. 6 illustrates a schematic cross-sectional view taken along line I-I′ of FIG. 3.

FIG. 7 illustrates a schematic top plan view of one of pixels of FIG. 3 according to an embodiment.

FIG. 8 illustrates a schematic cross-sectional view taken along line A-A′ of FIG. 7.

FIG. 9 illustrates a schematic cross-sectional view taken along line B-B′ of FIG. 7.

FIG. 10 illustrates a schematic flowchart of a method of manufacturing a display device according to an embodiment of this disclosure.

FIGS. 11, 12, 13, 14, and 15 schematically illustrate the method of manufacturing the display device of FIG. 10.

FIG. 16 illustrates a schematic flowchart of a method of manufacturing a display device according to another embodiment of this disclosure.

FIGS. 17, 18, 19, 20, 21, and 22 schematically illustrate the method of manufacturing the display device of FIG. 16.

FIG. 23 illustrates a schematic top plan view of a display panel of FIG. 1 according to another embodiment.

FIG. 24 illustrates a schematic cross-sectional view taken along line II-II′ of FIG. 23.

FIG. 25 illustrates a schematic top plan view of one of pixels of FIG. 23 according to an embodiment.

FIG. 26 illustrates a schematic cross-sectional view taken along line C-C′ of FIG. 25.

FIGS. 27, 28, 29, 30, and 31 schematically illustrate a method of manufacturing a display device according to another embodiment of this disclosure.

FIG. 32 illustrates a schematic cross-sectional view taken along line II-II′ of FIG. 23.

FIG. 33 illustrates a schematic block diagram of a display system according to an embodiment.

FIGS. 34, 35, 36, and 37 illustrate schematic perspective views of application examples of the display system of FIG. 33.

### DETAILED DESCRIPTION OF THE EMBODIMENTS

Hereinafter, example embodiments of this disclosure will be described in detail with reference to the accompanying drawings. The following description is intended to provide only a sufficient disclosure to enable the understanding of the operation of the invention, and any other disclosure is omitted to avoid obscuring the scope of the invention. In addition, the inventive concept may be embodied in different forms and is not limited to the embodiments set forth herein. The embodiments described herein are provided for the purpose of describing the technical concept of the invention in sufficient detail for those skilled in the art to easily practice it.

Throughout the specification, in case that it is described that an element is “connected” to another element, this includes not only being “directly connected”, but also being “indirectly connected” with another device therebetween. The terms used herein are for the purpose of describing specific embodiments and are not intended to limit the scope of the invention. Throughout the specification, unless explicitly described to the contrary, the word “comprise” and variations such as “comprises” or “comprising” will be understood to imply the inclusion of stated elements but not the exclusion of any other elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of this disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to sectional illustrations that are schematic illustrations of idealized embodiments. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

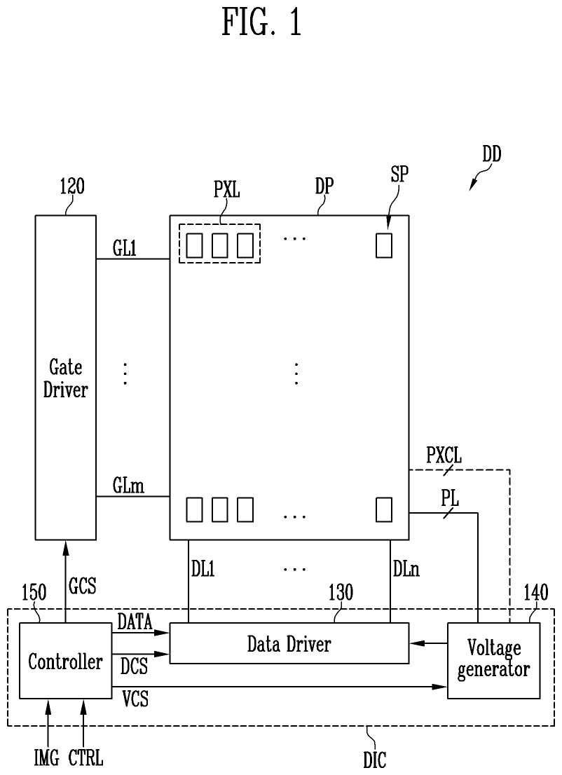

FIG. 1 illustrates a schematic block diagram of a display device according to an embodiment.

Referring to FIG. 1, a display device DD may include a display panel DP, a gate driver 120, a data driver 130, a voltage generator 140, and a controller 150.

The display panel DP may include sub-pixels SP. The sub-pixels SP may be electrically connected to the gate driver 120 through first to m-th gate lines GL1 to GLm. The sub-pixels SP may be electrically connected to the data driver 130 through first to n-th data lines DL1 to DLn.

The sub-pixels SP may generate light of two or more colors. For example, the sub-pixels SP may respectively generate light of a color, such as red, green, blue, cyan, magenta, yellow, or the like.

Two or more of the sub-pixels SP may configure one pixel PXL. For example, the pixel PXL may include three sub-pixels as shown in FIG. 1. The pixel PXL may emit light of various colors and various luminance depending on a combination of light emitted from the sub-pixels included therein.

The gate driver 120 may be electrically connected to the sub-pixels SP arranged in a row direction through the first to m-th gate lines GL1 to GLm. The gate driver 120 may output gate signals to the first to m-th gate lines GL1 to GLm in response to a gate control signal GCS. The gate control signal GCS may include a start signal indicating the start of each frame, a horizontal synchronization signal, and the like.

The gate driver 120 may be disposed on one side of the display panel DP. However, embodiments are not limited thereto. For example, the gate driver 120 may be divided into two or more physically and/or logically separated drivers, and the drivers may be disposed on one side of the display panel DP and another side of the display panel DP opposite to the one side. As described above, the gate driver 120 may be disposed around the display panel DP in various forms according to the embodiments.

The data driver 130 may be electrically connected to the sub-pixels SP arranged in a column direction through the first to n-th data lines DL1 to DLn. The data driver 130 may receive image data (DATA) and a data control signal DCS from the controller 150. The data driver 130 may operate in response to the data control signal DCS. The data control signal DCS may include a source start signal, a source shift clock, a source output enable signal, and the like.

The data driver 130 may receive voltages from the voltage generator 140. The data driver 130 may use the received voltages to apply data signals having grayscale voltages corresponding to the image data (DATA) to the first to n-th data lines DL1 to DLn. In case that a gate signal is applied to each of the first to m-th gate lines GL1 to GLm, data signals corresponding to the image data DATA may be applied to the data lines DL1 to DLn. Accordingly, the sub-pixels SP may generate light corresponding to the data signals, and the display panel DP may display an image (or images).

In other embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate multiple voltages and provide the generated voltages to components of the display device DD, such as the gate driver 120, the data driver 130, and the controller 150. The voltage generator 140 may generate multiple voltages by receiving an input voltage from the outside of the display device DD and regulating the received voltage.

The voltage generator 140 may generate a first power voltage and a second power voltage. The generated first and second power voltages may be provided to the sub-pixels SP through the power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation to sense electrical characteristics of transistors and/or light emitting elements of the sub-pixels SP, a predetermined reference voltage may be applied to the first to n-th data lines DL1 to DLn, and the voltage generator 140 may generate the reference voltage to transmit it to the data driver 130. For example, during a display operation for displaying an image on the display panel DP, common pixel control signals may be applied to the sub-pixels SP, and the voltage generator 140 may generate the pixel control signals. The voltage generator 140 may provide pixel control signals to the sub-pixels SP through a pixel control lines PXCL. FIG. 1 illustrates that the pixel control lines PXCL are electrically connected between the voltage generator 140 and the display panel DP, but the embodiments are not limited thereto. For example, the pixel control lines PXCL may be electrically connected between the gate driver 120 and the display panel DP. The pixel control signals may be transmitted from the voltage generator 140 to the pixel control lines PXCL through the gate driver 120.

The controller 150 may control various operations of the display device DD. The controller 150 may receive input image data IMG and a control signal CTRL corresponding thereto, from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP to output the image data DATA. The controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be functionally separate components in one driver integrated circuit DIC. In other embodiments, at least one of the data driver 130, the voltage generator 140, and the controller 150 may be provided as a component separated from the driver integrated circuit DIC.

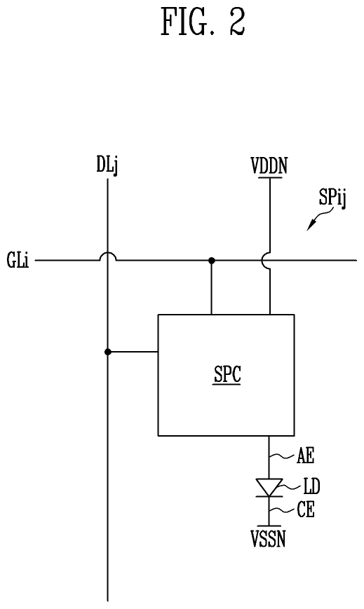

FIG. 2 illustrates a schematic block diagram of one of sub-pixels of FIG. 1 according to an embodiment. In FIG. 2, among the sub-pixels SP of FIG. 1, a sub-pixel SPij disposed in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light emitting element LD.

The light emitting element LD may be electrically connected between a first power voltage node VDDN and a second power voltage node VSSN. The first power voltage node VDDN may be electrically connected to one of the power lines PL in FIG. 1 to receive the first power voltage. The second power voltage node VSSN may be electrically connected to another one of the power lines PL in FIG. 1 to receive the second power voltage. The first power voltage may have a higher voltage level than the second power voltage.

The light emitting element LD may be electrically connected between the anode electrode AE and the cathode electrode CE. The anode electrode AE may be electrically connected to the first power voltage node VDDN through the sub-pixel circuit SPC. For example, the anode electrode AE may be electrically connected to the first power voltage node VDDN through one or more transistors included in the sub-pixel circuit SPC. The cathode electrode CE may be electrically connected to the second power voltage node VSSN. The light emitting element LD may emit light according to a current flowing from the anode electrode AE to the cathode electrode CE.

The sub-pixel circuit SPC may be electrically connected to an i-th gate line GLi of the first to m-th gate lines GL1 to GLm of FIG. 1 and a j-th data line DLj of the first to n-th data lines DL1 to DLn of FIG. 1. In response to the gate signal received through the i-th gate line GLi, the sub-pixel circuit SPC may control the light emitting element LD to emit light according to the data signal received through the j-th data line DLj. The sub-pixel circuit SPC may be further connected to the pixel control lines PXCL of FIG. 1. The sub-pixel circuit SPC may control the light emitting element LD in further response to pixel control signals received through the pixel control lines PXCL.

For these operations, the sub-pixel circuit SPC may include circuit elements, for example transistors and one or more capacitors.

The transistors of the sub-pixel circuit SPC may include P-type transistors and/or N-type transistors. The transistors of the sub-pixel circuit SPC may include a metal oxide silicon field effect transistor (MOSFET). The transistors of the sub-pixel circuit SPC may include an amorphous silicon semiconductor, a monocrystalline silicon semiconductor, a polycrystalline silicon semiconductor, and an oxide semiconductor.

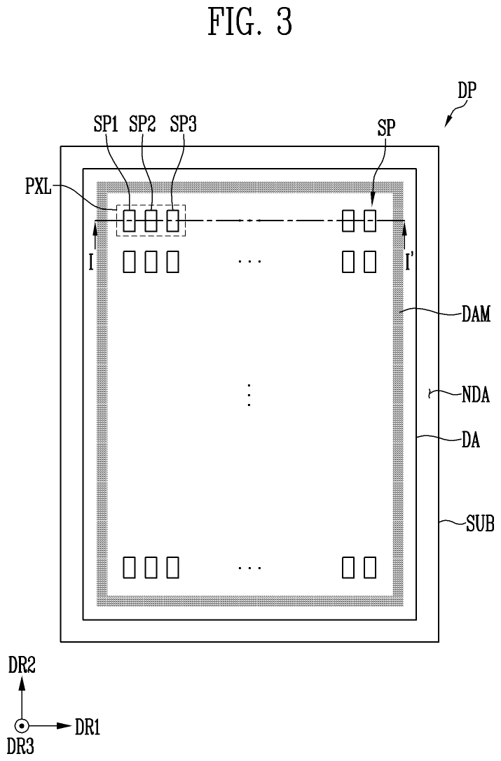

FIG. 3 illustrates a schematic top plan view of a display panel of FIG. 1 according to an embodiment.

Referring to FIG. 3, the display panel DP may include a display area DA and a non-display area NDA. The display panel DP may display an image through the display area DA. The non-display area NDA may be disposed around the display area DA.

The display panel DP may include sub-pixels SP in the display area DA. The sub-pixels SP may be arranged in a first direction DRI and a second direction DR2 that intersects the first direction DR1. For example, the sub-pixels SP may be arranged in a matrix format in the first direction DR1 and the second direction DR2. As another example, the sub-pixels SP may be arranged in a zigzag form in first direction DRI and second direction DR2. The arrangement of the sub-pixels SP may vary in other embodiments. The first direction DR1 may be a row direction, and the second direction DR2 may be a column direction.

Two or more of multiple sub-pixels SP may configure one pixel PXL. FIG. 3 illustrates that the pixel PXL includes three sub-pixels SP1 to SP3, but embodiments are not limited thereto. For example, the pixel PXL may include two sub-pixels. Hereinafter, for better understanding and ease of description, the pixel PXL may include the first to third sub-pixels SP1 to SP3.

Each of the first to third sub-pixels SP1 to SP3 may generate one of various colors such as red, green, blue, cyan, magenta, and yellow. Hereinafter, for clear and brief description, the first sub-pixel SP1 may generate red-colored light, the second sub-pixel SP2 may generate green-colored light, and the third sub-pixel SP3 may generate blue-colored light.

Each of the first to third sub-pixels SP1 to SP3 may include at least one light emitting element to generate light. The light emitting elements of the first to third sub-pixels SP1 to SP3 may generate light of the same color. For example, the light emitting elements of the first to third sub-pixels SP1 to SP3 may generate blue-colored light. In other embodiments, the light emitting elements of the first to third sub-pixels SP1 to SP3 may generate light of different colors. For example, the light emitting elements of the first to third sub-pixels SP1 to SP3 may generate light of red, green, and blue colors, respectively.

As the display panel DP, a self-luminous display panel such as an LED display panel using a micro-scale or nano-scale light emitting diode as a light emitting element and an organic light emitting display panel using an organic light emitting diode as a light emitting element may be used.

The display panel DP may include a dam member DAM in the display area DA. The dam member DAM may be disposed at an edge of the display area DA. The dam member DAM may be disposed in a closed loop at the edge of the display area DA. For example, in case that the display panel DP is provided in a rectangular shape with a pair of short sides and a pair of long sides, the dam member DAM may be disposed in the closed loop at the edge by extending in the first direction DRI along the short sides at the edge of the display area DA and extending in the second direction DR2 along the long sides.

A constituent element to control the sub-pixels SP may be disposed in the non-display area NDA. Wires electrically connected to the sub-pixels SP, for example, the first to m-th gate lines GL1 to GLm, the first to n-th data lines DL1 to DLn, the power lines PL, and the pixel control lines PXCL shown in FIG. 1 may be disposed in the non-display area NDA.

At least one of the gate driver 120, the data driver 130, the voltage generator 140, and the controller 150 in FIG. 1 may be disposed in the non-display area NDA of the display panel DP. The gate driver 120 may be disposed in the non-display area NDA. The data driver 130, the voltage generator 140, and the controller 150 may be implemented as the driver integrated circuit DIC of FIG. 1 separated from the display panel DP, and the driver integrated circuit DIC may be electrically connected to wires disposed in the non-display area NDA. In other embodiments, the gate driver 120 may be implemented as one integrated circuit separated from the display panel DP together with the data driver 130, the voltage generator 140, and the controller 150.

The display area DA may have various shapes. The display area DA may have a closed-loop shape including sides of a straight line and/or a curved line. For example, the display area DA may have shapes such as a polygonal shape, a circular shape, a semicircular, and an elliptical shape.

The display panel DP may have a flat display surface. In other embodiments, the display panel DP may have a display surface that is at least partially round. The display panel DP may be bendable, foldable, or rollable. In these cases, the display panel DP and/or the substrate of the display panel DP may include materials with flexible properties.

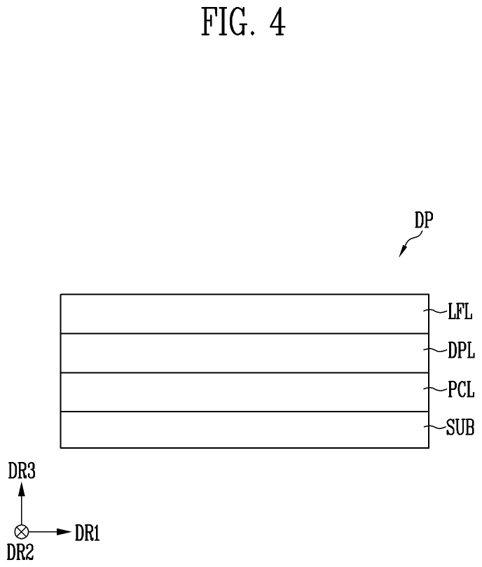

FIG. 4 illustrates a schematic cross-sectional view of a display panel of FIG. 3 according to an embodiment.

Referring to FIG. 4, the display panel DP may include a substrate SUB, and a pixel circuit layer PCL, a display element layer DPL, and a light functional layer LFL, which are sequentially stacked on the substrate SUB in a third direction DR3 intersecting the first and second directions DR1 and DR2.

The substrate SUB may be made of an insulating material such as glass or a resin. For example, the substrate SUB may include a glass substrate. As another example, the substrate SUB may include a polyimide (PI) substrate. As yet another example, the substrate SUB may include a silicon wafer substrate formed using a semiconductor process.

The substrate SUB may be made of a flexible material to be bendable or foldable, and may have a single-layered structure or a multi-layered structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, wires, and the like.

The circuit elements of the pixel circuit layer PCL may include the sub-pixel circuit SPC (see FIG. 2) of each of the sub-pixels SP of FIG. 3. For example, the circuit elements of the pixel circuit layer PCL may be provided as transistors and one or more capacitors of the sub-pixel circuit SPC.

The wires of the pixel circuit layer PCL may include wires electrically connected to the sub-pixels SP. The wires of the pixel circuit layer PCL may include various signal lines and/or voltage lines required to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may change the wavelength (or color) of light emitted from the display element layer DPL. The light functional layer LFL may further include light scattering patterns with scattering particles. The light conversion patterns and the light scattering patterns may be omitted.

The light functional layer LFL may further include a color filter layer including color filters. The color filter may selectively transmit light of a specific wavelength (or a specific color). The color filter layer may be omitted.

A window for protecting an exposed surface (or upper surface) of the display panel DP may be provided on the light functional layer LFL. The window may protect the display panel DP from external impact (or force). The window may be coupled to the light functional layer LFL through an optically transparent adhesive (bonding) member. The window may have a multi-layered structure selected from a glass substrate, a plastic film, and a plastic substrate. The multi-layered structure may be formed through a continuous process or an adhesive process using an adhesive layer. All or a portion of the window may be flexible.

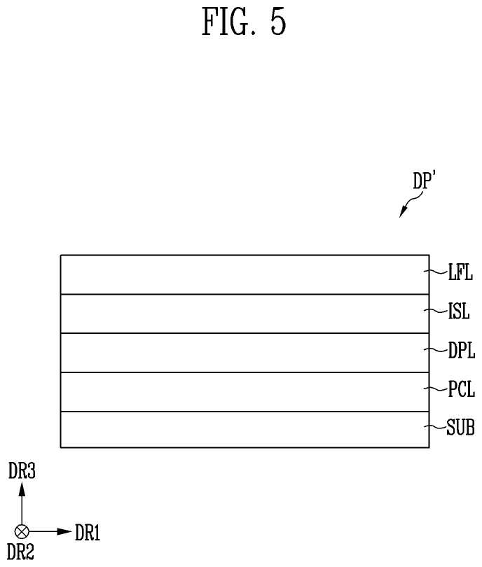

FIG. 5 illustrates a schematic cross-sectional view of a display panel of FIG. 3 according to another embodiment.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL of FIG. 5 are similarly configured to the substrate SUB, the pixel circuit layer PCL, the display element layer DPL, and the light functional layer LFL described with reference to FIG. 4, respectively. Hereinafter, redundant descriptions thereof will be omitted.

The input sensing layer ISL may detect a user input on an upper surface (or display surface) of the display panel DP′. The input sensing layer ISL may include components suitable for sensing an external object such as a user's hand or pen. For example, the input sensing layer ISL may include touch electrodes.

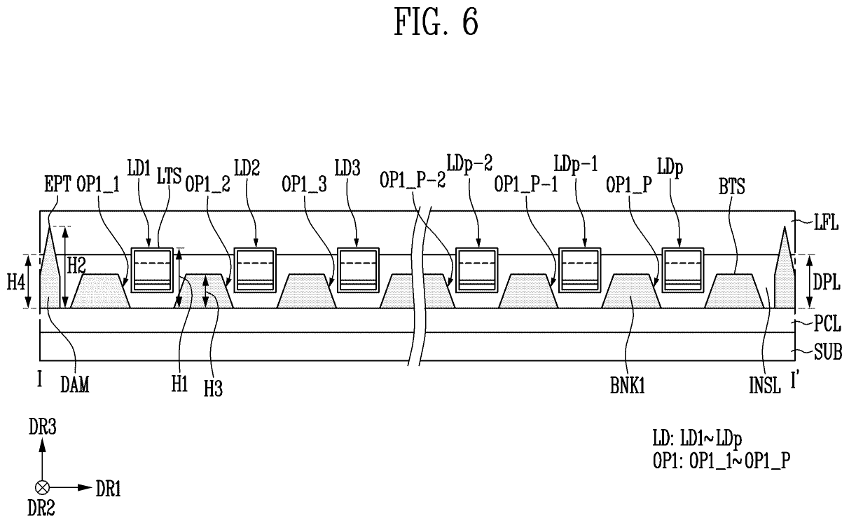

FIG. 6 illustrates a schematic cross-sectional view taken along line I-I′ of FIG. 3.

Referring to FIG. 3 and FIG. 6, the pixel circuit layer PCL, the display element layer DPL, and the light functional layer LFL may be sequentially disposed in the third direction DR3 on the substrate SUB. The display element layer DPL may include an insulating layer INSL, light emitting elements LD, a first bank BNK1, and a dam member (or dam structure) DAM. The insulating layer INSL may include an overcoat layer OCL and a third passivation layer PSV3.

The first bank BNK1 may be disposed on the display area DA of the substrate SUB (or the pixel circuit layer PCL). The first bank BNK1 may have first openings OP1 corresponding to the light emitting areas of the sub-pixels SP in the third direction DR3. For example, the first bank BNK1 may surround the light emitting elements LD disposed in the sub-pixels SP and may have the first openings OP1 corresponding to the light emitting areas of respective light emitting elements LD.

The light emitting elements LD may be disposed on the display area DA of the substrate SUB (or the pixel circuit layer PCL). The light emitting elements LD may be arranged in the first direction DR1 and/or the second direction DR2. The light emitting elements LD may each overlap the first openings OP1 which are spaced apart from each other. The light emitting elements LD may be at least partially disposed in the first openings OP1. For example, the first to p-th light emitting elements LD1 to LDp may overlap the (1_1)-th to (1_p)-th openings OP1_1 to OP1_p, respectively. The first to p-th light emitting elements LD1 to LDp may be at least partially disposed in the (1_1)-th to (1_p)-th openings OP1_1 to OP1_p, respectively.

The dam member DAM may be disposed on the display area DA of the substrate SUB (or the pixel circuit layer PCL). The dam member DAM may be disposed along an edge of the display area DA. The dam member DAM may be disposed to surround the display area DA in which the light emitting elements LD are disposed in a plan view. For example, in case that the first to p-th light emitting elements LD1 to LDp are arranged in the first direction DR1, the dam member DAM may be disposed in a direction opposite to the first direction DR1 of the first light emitting element LD1. The dam member DAM may be disposed in the first direction DRI of the p-th light emitting element LDp. The dam member DAM may be disposed outside the light emitting elements LD in the first direction DR1 and in a direction opposite to the first direction DR1. In addition, although not shown in FIG. 6, in case that the light emitting elements LD are arranged in the second direction DR2, the dam member DAM may be disposed outside the light emitting elements LD in the second direction DR2 and in a direction opposite to the second direction DR2.

The dam member DAM may be integrally formed with the first bank BNK1, but is not limited thereto, and the dam member DAM may be formed separately from the first bank BNK1.

Each of the light emitting elements LD may have a first height H1 in the third direction DR3 intersecting the first and second directions DR1 and DR2. The first height H1 may be a distance between the substrate SUB (or the pixel circuit layer PCL) and the upper surface LTS opposite to the substrate SUB of the light emitting element LD in the third direction DR3. The dam member DAM may have a second height H2 greater than the first height H1 in the third direction DR3. The second height H2 may be a distance between the substrate SUB (or the pixel circuit layer PCL) and the end EPT opposite to the substrate SUB of the dam member DAM in the third direction DR3. For example, the dam member DAM may be disposed on the pixel circuit layer PCL to protrude further in the third direction DR3 than the light emitting elements LD.

The first bank BNK1 may be disposed on the pixel circuit layer PCL and may have a third height H3 less than the second height H2 of the dam member DAM in the third direction DR3. The third height H3 may be a distance between the substrate SUB (or the pixel circuit layer PCL) and the upper surface BTS opposite to the substrate SUB of the first bank BNK1 in the third direction DR3. Since the first bank BNK1 has the third height H3 less than the first height H1 of the light emitting elements LD, the light emitting elements LD may protrude further in the third direction DR3 than the first bank BNK1.

The display element layer DPL may have a fourth height H4 less than the second height H2 of the dam member DAM in the third direction DR3. For example, the fourth height H4 may be less than the first height H1, but greater than the third height H3 in the third direction DR3. Accordingly, unlike the first bank BNK1, the dam member DAM may protrude from the display element layer DPL to the light functional layer LFL.

In other embodiments, the dam member DAM may be disposed to protrude in a direction opposite to the substrate SUB along the edge of the display area DA. For example, the dam member DAM may be disposed on the same layer as the first bank BNK1 to protrude in the third direction DR3 than the light emitting elements LD.

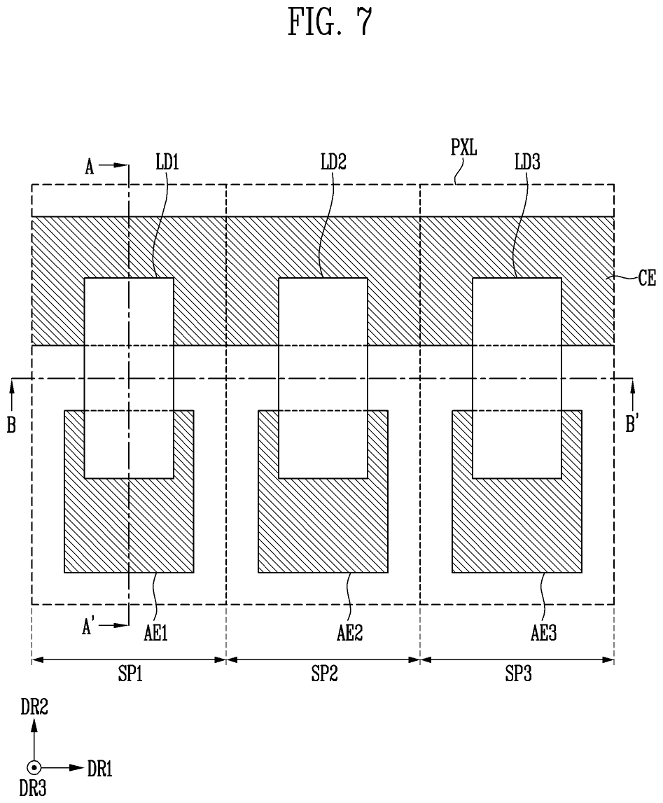

FIG. 7 illustrates a schematic top plan view of one of pixels of FIG. 3 according to an embodiment.

Referring to FIG. 7, the pixel PXL may include the first to third sub-pixels SP1 to SP3. The first to third sub-pixels SP1 to SP3 may be arranged in the first direction DR1. However, the arrangement of pixels PXL is not limited thereto, and may be variously changed in other embodiments. For example, the first to third sub-pixels SP1 to SP3 may be arranged in a zigzag pattern (or shape).

First to third anode electrodes AE1 to AE3 may be disposed in the first to third sub-pixels SP1 to SP3, respectively. The first anode electrode AE1 may be provided as the anode electrode AE (see FIG. 2) electrically connected to the sub-pixel circuit SPC (see FIG. 2) of the first sub-pixel SP1. The second anode electrode AE2 may be provided as the anode electrode AE electrically connected to the sub-pixel circuit SPC of the second sub-pixel SP2. The third anode electrode AE3 may be provided as the anode electrode AE electrically connected to the sub-pixel circuit SPC of the third sub-pixel SP3.

The cathode electrode CE may be spaced apart from the first to third anode electrodes AE1 to AE3. The cathode electrode CE may be disposed at the same height as the first to third anode electrodes AE1 to AE3. The cathode electrode CE may be spaced apart from the first to third anode electrodes AE1 to AE3 in the second direction DR2. The cathode electrode CE may extend in the first direction DR1 and be used as a common electrode for the pixel PXL and other pixels adjacent to the pixel PXL. Although not shown, the cathode electrode CE extends not only in the first direction DR1 but also in the second direction DR2 and may be used as a common electrode for all of the sub-pixels SP of FIG. 3. The cathode electrode CE may have various shapes.

First to third light emitting elements LD1 to LD3 may be disposed on the first to third anode electrodes AE1 to AE3 and the cathode electrode CE. The first light emitting element LD1 may be electrically connected to the first anode electrode AE1 and the cathode electrode CE. The first light emitting element LD1 may be provided as the light emitting element LD (see FIG. 2) electrically connected to the sub-pixel circuit SPC of the first sub-pixel SP1. The second light emitting element LD2 may be electrically connected to the second anode electrode AE2 and the cathode electrode CE. The second light emitting element LD2 may be provided as the light emitting element LD electrically connected to the sub-pixel circuit SPC of the second sub-pixel SP2. The third light emitting element LD3 may be electrically connected to the third anode electrode AE3 and the cathode electrode CE. The third light emitting element LD3 may be provided as the light emitting element LD electrically connected to the sub-pixel circuit SPC of the third sub-pixel SP3.

The first light emitting element LD1, the second light emitting element LD2, and the third light emitting element LD3 may be inorganic light emitting diodes containing an inorganic light emitting material. However, embodiments are not limited thereto and, for example, organic light emitting diodes may be used.

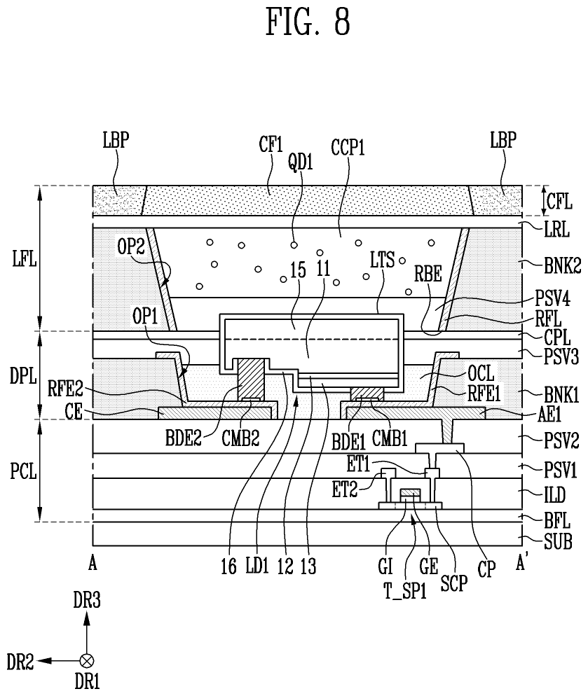

FIG. 8 illustrates a schematic cross-sectional view taken along line A-A′ of FIG. 7.

Referring to FIG. 7 and FIG. 8, the pixel circuit layer PCL, the display element layer DPL, and the light functional layer LFL may be sequentially disposed on the substrate SUB in the third direction DR3.

The pixel circuit layer PCL may include insulating layers, semiconductor patterns, and conductive patterns stacked on the substrate SUB. The insulating layers may include a buffer layer BFL, one or more interlayer insulating layers ILD, and one or more passivation layers PSV1 and PSV2. The semiconductor patterns and the conductive patterns may be disposed between the insulating layers. The conductive patterns may include at least one of copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of each of the first to third sub-pixels SP1 to SP3 may include transistors and one or more capacitors. The semiconductor patterns and conductive patterns of the pixel circuit layer PCL may function as transistors and capacitors of the sub-pixel circuit SPC. The conductive patterns of the pixel circuit layer PCL may further function as wires, for example, the first to m-th gate lines GL1 to GLm, the first to n-th data lines DL1 to DLn, the power lines PL, and the pixel control lines PXCL in FIG. 1.

The buffer layer BFL may be disposed on the substrate SUB. The buffer layer BFL may prevent impurities from diffusing into the circuit elements and wires included in the pixel circuit layer PCL. The buffer layer BFL may include an inorganic insulating layer including an inorganic material. The buffer layer BFL may include at least one of metal oxides such as a silicon nitride (SiNₓ), a silicon oxide (SiOₓ), a silicon oxynitride (SiOₓN_{y}), and an aluminum oxide (AlOₓ). The buffer layer BFL may be provided as a single layer or multiple layers. In case that the buffer layer BFL is provided as the multiple layers, respective layers thereof may be made of the same material or different materials.

One or more barrier layers may be disposed between the substrate SUB and the buffer layer BFL. Each of the barrier layers may include polyimide.

A transistor T_SP1 may be disposed on the buffer layer BFL. The transistor T SP1 may be one of the transistors of the sub-pixel circuit SPC included in the first sub-pixel SP1. For example, the transistor T_SP1 may be understood as a transistor electrically connected to the first anode electrode AE1 among transistors of the sub-pixel circuit SPC.

The transistor T_SP1 may include a semiconductor pattern SCP, a gate electrode GE, a first terminal ET1, and a second terminal ET2. The first terminal ET1 may be one of a source electrode and a drain electrode, and the second terminal ET2 may be another of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact area in contact with the first terminal ET1 and a second contact area in contact with the second terminal ET2. An area between the first contact area and the second contact area may be a channel area. The channel area may overlap the gate electrode GE of the transistor T_SP1. The channel area may be a semiconductor pattern that is not doped with impurities, and may be an intrinsic semiconductor. The first contact area and the second contact area may be semiconductor patterns doped with impurities. As the impurities, for example, p-type impurities may be used, but embodiments are not limited thereto.

The semiconductor pattern SCP may include one of various types of semiconductors, for example, one of an amorphous silicon semiconductor, a monocrystalline silicon semiconductor, a polycrystalline silicon semiconductor, a low temperature polysilicon semiconductor, and an oxide semiconductor.

Interlayer insulating layers ILD sequentially stacked on the semiconductor pattern SCP may be disposed. The interlayer insulating layers ILD may be inorganic insulating layers including an inorganic material. For example, each of the interlayer insulating layers ILD may include at least one of metal oxides such as a silicon nitride (SiNₓ), a silicon oxide (SiOₓ), a silicon oxynitride (SiOₓN_{y}), and an aluminum oxide (AlOₓ). However, the interlayer insulating layers ILD are not limited thereto. For example, one of the interlayer insulating layers ILD may include an organic insulating layer including an organic material.

The interlayer insulating layers ILD may electrically separate conductive patterns and/or semiconductor patterns disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE so that the gate electrode GE is spaced apart from the semiconductor pattern SCP. The gate insulating layer GI may be entirely provided on the semiconductor pattern SCP and the buffer layer BFL to cover the semiconductor pattern SCP and the buffer layer BFL. As the number of layers required to form conductive patterns and/or semiconductor patterns increases, the number of the interlayer insulating layers ILD may increase.

The gate electrode GE may be disposed on the gate insulating layer GI. The gate electrode GE may overlap the channel area of the semiconductor pattern SCP. The gate electrode GE may be provided as a single layer including at least one of copper (Cu), molybdenum (Mo), tungsten (W), aluminum neodymium (AlNd), titanium (Ti), aluminum (Al), and silver (Ag). The gate electrode GE may be provided as a multilayer including at least one of molybdenum (Mo), titanium (Ti), copper (Cu), aluminum (Al), and silver (Ag), which are low-resistance materials.

The first and second terminals ET1 and ET2 may be disposed on the interlayer insulating layers ILD. The first and second terminals ET1 and ET2 may contact the semiconductor pattern SCP through contact holes penetrating the interlayer insulating layers

ILD. The first and second terminals ET1 and ET2 may contact the first and second contact areas of the semiconductor pattern SCP, respectively. Each of the first and second terminals ET1 and ET2 may include at least one of copper (Cu), molybdenum (Mo), tungsten (W), aluminum neodymium (AlNd), titanium (Ti), aluminum (Al), and silver (Ag).

Although the first and second terminals ET1 and ET2 are illustrated as separate electrodes electrically connected to the semiconductor pattern SCP, the embodiments are not limited thereto. The first terminal ET1 may be a first contact area adjacent to one side of the channel area of the semiconductor pattern SCP, and the second terminal ET2 may be a second contact area adjacent to another side of the channel area thereof. The first terminal ET1 may be electrically connected to the light emitting element LD through a connection member such as a bridge electrode disposed on at least one of the interlayer insulating layers ILD.

The transistor T_SP1 may be a low-temperature polysilicon transistor. However, embodiments are not limited thereto. For example, the transistor T_SP1 may be an oxide semiconductor transistor. The sub-pixel circuit of the first sub-pixel SP1 may include different types of transistors. For example, the transistor T_SP1 may be a low-temperature polysilicon transistor, and another transistor of the first sub-pixel SP1 may be an oxide semiconductor transistor. The oxide semiconductor of the corresponding oxide semiconductor transistor may be disposed on one of the interlayer insulating layers ILD, rather than the insulating layer in which the semiconductor pattern SCP of the transistor T_SP1 is disposed.

The case in which the transistor T_SP1 is a transistor with a top gate structure has been described as an example, but the embodiments are not limited thereto. For example, the transistor T_SP1 may be a transistor with a bottom gate structure. The structure of the transistor T_SP1 may be variously changed.

At least some of the various wires of the display panel DP and/or the display device DD may be further disposed on the interlayer insulating layers ILD.

A first passivation layer PSV1 may be disposed on the interlayer insulating layers ILD and the first and second terminals ET1 and ET2. The passivation layer may also be referred to as a protective layer or via layer. The first passivation layer PSV1 may protect components disposed thereunder, and may provide a flat upper surface.

A connection pattern CP may be disposed on the first passivation layer PSV1. The connection pattern CP may penetrate the first passivation layer PSVI to be electrically connected to the first terminal ET1 of the transistor T_SP1. The connection pattern CP may include at least one of copper (Cu), molybdenum (Mo), tungsten (W), aluminum neodymium (AlNd), titanium (Ti), aluminum (Al), and silver (Ag).

At least some of the various wires of the display panel DP and/or the display device DD may be further disposed on the first passivation layer PSV1.

A second passivation layer PSV2 may be disposed on the connection pattern CP and the first passivation layer PSV1. The second passivation layer PSV2 may protect components disposed thereunder, and may provide a flat upper surface.

Each of the first and second passivation layers PSV1 and PSV2 may include an inorganic insulating layer including an inorganic material and/or an organic insulating layer including an organic material. The inorganic insulating layer may include, for example, at least one of metal oxides such as a silicon oxide (SiOₓ), a silicon nitride (SiNₓ), a silicon nitride (SiOₓN_{y}), and an aluminum oxide (AlOₓ). The organic insulating layer may include at least one of, for example, an acrylic resin, an epoxy resin, a phenol resin, a polyamide resin, a polyimide resin, an unsaturated polyester resin, a poly-phenylene ether resin, a poly-phenylene sulfide resin, and a benzocyclobutene resin.

The first and second passivation layers PSV1 and PSV2 may include the same material as one of the interlayer insulating layers ILD, but embodiments are not limited thereto. Each of the first and second passivation layers PSV1 and PSV2 may be provided as a single layer, but may be provided as a multilayer.

The display element layer DPL may be disposed on the second passivation layer PSV2. The display element layer DPL may include a first anode electrode AE1, a cathode electrode CE, a first bank BNK1, first and second reflective electrodes RFE1 and RFE2, a first light emitting element LD1, an overcoat layer OCL, a third passivation layer PSV3, and a capping layer CPL.

The first anode electrode AE1 and the cathode electrode CE may be disposed on the pixel circuit layer PCL.

The first anode electrode AE1 may be electrically connected to the connection pattern CP through a contact hole penetrating the second passivation layer PSV2. For example, the first anode electrode AE1 may be electrically connected to the first transistor T SP1.

The cathode electrode CE may be spaced apart from the first anode electrode AE1 in the first direction DR1. The cathode electrode CE may be electrically connected to the second power voltage node VSSN of FIG. 2. Accordingly, the second power voltage applied to the second power voltage node VSSN may be transmitted to the cathode electrode CE.

The first bank BNK1 may be disposed on the first anode electrode AE1 and the cathode electrode CE. The first bank BNK1 may have a first opening OP1 exposing portions of the first anode electrode AE1 and the cathode electrode CE. The first light emitting element LD1 may be disposed in the first opening OP1 of the first bank BNK1. The first bank BNK1 may be provided as a pixel defining film defining an area in which the first light emitting element LD1 is disposed.

The first bank BNK1 may include a light-blocking material, thereby preventing light mixing between adjacent sub-pixels. The first bank BNK1 may include an organic material. For example, the first bank BNK1 may include an organic insulating material such as an acrylic resin, an epoxy resin, a phenol resin, a polyamide resin, a polyimide resin, or the like.

The first reflective electrode RFE1 may be disposed on an exposed portion of the first anode electrode AE1 and a side surface of the first bank BNK1 adjacent the first anode electrode AE1. The second reflective electrode RFE2 may be disposed on an exposed portion of the cathode electrode CE and a side surface of the first bank BNK1 adjacent the cathode electrode CE. The first and second reflective electrodes RFE1 and RFE2 may include conductive materials suitable for reflecting light. Accordingly, the light emitting efficiency of the first light emitting element LD1 may be improved. The first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom. embodiments are not limited thereto.

The first light emitting element LD1 may be electrically connected to the first anode electrode AE1 through the first reflective electrode RFE1. The first light emitting element LD1 may be electrically connected to the cathode electrode CE through the second reflective electrode RFE2. The first light emitting element LD1 may be bonded to and coupled to the first and second reflective electrodes RFE1 and RFE2.

The first light emitting element LD1 may include a first semiconductor layer 11, an active layer 12, a second semiconductor layer 13, and an auxiliary layer 15. The first light emitting element LD1 may include a light emitting stack in which the auxiliary layer 15, the first semiconductor layer 11, the active layer 12, and the second semiconductor layer 13 are sequentially stacked in the third direction DR3.

The first light emitting element LD1 may include first and second bonding electrodes BDE1 and BDE2 facing in the same direction (for example, a direction opposite to the third direction DR3). The first bonding electrode BDE1 may be electrically connected to the second semiconductor layer 13. The second bonding electrode BDE2 may be electrically connected to the first semiconductor layer 11 exposed by etching the second semiconductor layer 13 and the active layer 12. The first light emitting element LD1 may be a flip chip type light emitting element.

The first semiconductor layer 11 may provide electrons to the active layer 12. For example, the first semiconductor layer 11 may include at least one n-type semiconductor layer. For example, the first semiconductor layer 11 may include one of gallium nitride (GaN), aluminum gallium nitride (AlGaN), indium gallium nitride (InGaN), aluminum nitride (AlN), and indium nitride (InN), and may be an n-type semiconductor layer doped with a first conductive dopant (or n-type dopant) such as silicon (Si), germanium (Ge), tin (Sn), and the like. However, the material included in the first semiconductor layer 11 is not limited thereto, and the first semiconductor layer 11 may be made of various materials. For example, the first semiconductor layer 11 may include a gallium nitride (GaN) semiconductor material doped with the first conductive dopant (or n-type dopant). In other embodiments, the first semiconductor layer 11 may form an n-type semiconductor layer together with the auxiliary layer 15.

The active layer 12 may be disposed on the first semiconductor layer 11 in which electrons and holes are recombined. As the electrons and holes are recombined in the active layer 12, the electrons and holes may move to a low energy level, and accordingly, light having a wavelength corresponding to the low energy level may be generated. The active layer 12 may have a single or multiple quantum well structure. In case that the active layer 12 is formed in a multi-quantum well structure, units including a barrier layer, a strain reinforcing layer, and a well layer may be repeatedly stacked to form the active layer 12. However, embodiments of the active layer 12 are not limited thereto.

The second semiconductor layer 13 may be disposed on the active layer 12, and provide a hole in the active layer 12. The second semiconductor layer 13 may include a semiconductor layer of a type different from that of the first semiconductor layer 11. For example, the second semiconductor layer 13 may include at least one p-type semiconductor layer. For example, the second semiconductor layer 13 may include at least one of gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or p-type dopant) such as magnesium (Mg), zinc (Zn), calcium (Ca), strontium (Sr), barium (Ba), and the like. However, the material included in the second semiconductor layer 13 is not limited thereto, and the second semiconductor layer 13 may be formed of various materials. For example, the second semiconductor layer 13 may include a gallium nitride (GaN) semiconductor material doped with the second conductive dopant (or p-type dopant).

The auxiliary layer 15 may include a gallium nitride (GaN) semiconductor material that is not doped with impurities, and may form an n-type semiconductor layer together with the first semiconductor layer 11.

The first bonding electrode BDE1 may be electrically connected to the second semiconductor layer 13. The second bonding electrode BDE2 may be electrically connected to the first semiconductor layer 11. The first and second bonding electrodes BDE1 and BDE2 may include eutectic metal.

The first light emitting element LD1 may further include an insulating film 16 covering the outer peripheral surface of the light emitting stack (or structure). The insulating film 16 may prevent an electrical short circuit that may occur in case that the active layer 12 contacts other conductive materials other than the first and second semiconductor layers 11 and 13. The insulating film 16 may include a transparent insulating material. The insulating film 16 may expose lower surfaces of the first and second bonding electrodes BDE1 and BDE2.

A first coupling member CMB1 may be disposed between the first light emitting element LD1 and the first anode electrode AE1. A second coupling member CMB2 may be disposed between the first light emitting element LD1 and the cathode electrode CE. The first and second coupling members CMB1 and CMB2 may be disposed on one surface of the light emitting stack facing the substrate SUB. The first and second coupling members CMB1 and CMB2 may be disposed on one surface of the first and second bonding electrodes BDE1 and BDE2. The first coupling member CMB1 may be disposed between the first bonding electrode BDE1 and the first anode electrode AE1. The second coupling member CMB2 may be disposed between the second bonding electrode BDE2 and the cathode electrode CE.

The first and second coupling members CMB1 and CMB2 may be bonded to the first and second reflective electrodes RFE1 and RFE2. The first and second coupling members CMB1 and CMB2 and the first and second reflective electrodes RFE1 and RFE2 may be bonded by applying heat to areas in contact with each other. In the areas in which the first and second coupling members CMB1 and CMB2 are in contact with the first and second reflective electrodes RFE1 and RFE2, the first and second coupling members CMB1 and CMB2 and the first and second reflective electrodes RFE1 and RFE2 may be bonded to each other by forming an alloy.

The first and second coupling members CMB1 and CMB2 may include an Sn—Ag—Cu (SAC) alloy. However, this is an example, and the first and second coupling members CMB1 and CMB2 may include various known metal materials and/or alloys of at least two or more metal materials selected therefrom.

A lower surface of the first bonding electrode BDE1 may be in contact with the first reflective electrode RFE1. Accordingly, the first bonding electrode BDE1 may be electrically connected to the first anode electrode AE1 through the first reflective electrode RFE1. A lower surface of the second bonding electrode BDE2 may be in contact with the second reflective electrode RFE2. Accordingly, the second bonding electrode BDE2 may be electrically connected to the cathode electrode CE through the second reflective electrode RFE2.

The overcoat layer OCL may be disposed in the first opening OP1 in which the first and second reflective electrodes RFE1 and RFE2 and the first light emitting element LD1 are disposed. The overcoat layer OCL may fixedly bond the first light emitting element LD1 to the first and second reflective electrodes RFE1 and RFE2 so that the first light emitting element LD1 does not move. The overcoat layer OCL may protect components disposed thereunder from foreign substances such as dust and moisture. For example, the overcoat layer OCL may include at least one of an inorganic insulating film and an organic insulating film. For example, the overcoat layer OCL may include an epoxy resin, but embodiments are not limited thereto.

The third passivation layer PSV3 may be disposed on the first bank BNK1 and the overcoat layer OCL. The third passivation layer PSV3 may protect components disposed thereunder, and may provide a flat upper surface. The third passivation layer PSV3 may include the same material as one of the first and second passivation layers PSV1 and PSV2, but embodiments are not limited thereto.

The third passivation layer PSV3 may not be disposed on the upper surface LTS of the first light emitting element LD1. The first light emitting element LD1 may protrude into the light functional layer LFL. The first light emitting element LD1 may be disposed at least partially in the second opening OP2 of the second bank BNK2. For example, the height of the upper surface LTS of the first light emitting element LD1 from the substrate SUB may be higher than the lowermost end RBE of the reflective layer RFL. Accordingly, the light emitted from the first light emitting element LD1 may be provided to the light functional layer LFL at a relatively high ratio.

The capping layer CPL may be disposed on the third passivation layer PSV3. The capping layer CPL may protect components under the capping layer CPL, such as the first light emitting element LD1, from external moisture and humidity. The capping layer CPL may not be disposed on the upper surface of the first light emitting element LD1. In other embodiments, the capping layer CPL may entirely cover the first light emitting element LD1 and the third passivation layer PSV3. The capping layer CPL may include at least one of metal oxides such as a silicon nitride (SiNₓ), a silicon oxide (SiOₓ), a silicon oxynitride (SiOₓN_{y}), and an aluminum oxide (AlOₓ). However, the material of the capping layer CPL is not limited thereto.

The pixel circuit layer PCL and the display element layer DPL of the first sub-pixel SP1 have been described above. Each of the second and third sub-pixels SP2 and SP3 of FIG. 6 may be similarly configured to the first sub-pixel SP1, in a range not otherwise described herein.

The light functional layer LFL may be disposed on the capping layer CPL. The light functional layer LFL may include a second bank BNK2, a reflective layer RFL, a fourth passivation layer PSV4, a first light conversion pattern CCP1, a low refractive index layer LRL, and a color filter layer CFL.

The second bank BNK2 may be disposed on the capping layer CPL. The second bank BNK2 may overlap the first bank BNK1 in the third direction DR3. The second bank BNK2 may have a second opening OP2 overlapping the first opening OP1. For example, a diameter of the second opening OP2 may be greater than a diameter of the first opening OP1 in a plan view.

The second bank BNK2 may include a light blocking material to prevent light mixing between adjacent sub-pixels. The second bank BNK2 may include an organic material. For example, the second bank BNK2 may include an organic insulating material such as an acrylic resin, an epoxy resin, a phenol resin, a polyamide resin, a polyimide resin, or the like.

The reflective layer RFL may be disposed on side surfaces of the second bank BNK2 adjacent to the second opening OP2. The reflective layer RFL may reflect incident light, thereby improving outgoing light efficiency. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and an alloy of two or more materials selected therefrom. However, embodiments are not limited thereto.

The fourth passivation layer PSV4 may be disposed in the second opening OP2 on the capping layer CPL. The fourth passivation layer PSV4 may protect components disposed thereunder, and may provide a flat upper surface. The fourth passivation layer PSV4 may include the same material as one of the first to third passivation layers PSV1 to PSV3, but embodiments are not limited thereto.

The first light conversion pattern CCP1 may be disposed in the second opening OP2 on the fourth passivation layer PSV4.

The first light conversion pattern CCP1 may include color conversion particles and/or scattering particles. The color conversion particles may convert the incident light into light of a different color by changing the wavelength of the incident light. The color conversion particles may scatter the incident light. The color conversion particles may be quantum dots. However, embodiments are not limited thereto. The scattering particles may scatter incident light.

The first sub-pixel SP1 may be a red sub-pixel. In case that the first light emitting element LD1 emits blue-colored light, the first light conversion pattern CCP1 may include first color conversion particles QD1 to convert blue-colored light into red-colored light. In case that the first light emitting element LD1 emits red-colored light, the first light conversion pattern CCP1 may include scattering particles. The particles included in the first light conversion pattern CCP1 may be variously changed according to the first light emitting element LD1.

The low refractive index layer LRL may be disposed on the second bank BNK2, the reflective layer RFL, and the first light conversion pattern CCP1. The low refractive index layer LRL may have a lower refractive index than the first light conversion pattern CCP1. The low refractive index layer LRL may refract or totally reflect the corresponding light according to an incident angle of the light. For example, the low refractive index layer LRL may provide light that has passed through the first light conversion pattern CCP1 back to the first light conversion pattern CCP1. Accordingly, the light conversion efficiency of the first light conversion pattern CCP1 may be improved.

The color filter layer CFL may be disposed on the low refractive index layer LRL. The color filter layer CFL may include a first color filter CF1 and a light blocking patterns LBP. The first color filter CF1 may overlap the first light conversion pattern CCP1 in the third direction DR3. The first color filter CF1 may selectively transmit light in a desired wavelength range. In case that the first sub-pixel SP1 is a red sub-pixel, the first color filter CF1 may include a red color filter. The light blocking patterns LBP may include at least one of various types of light blocking materials.

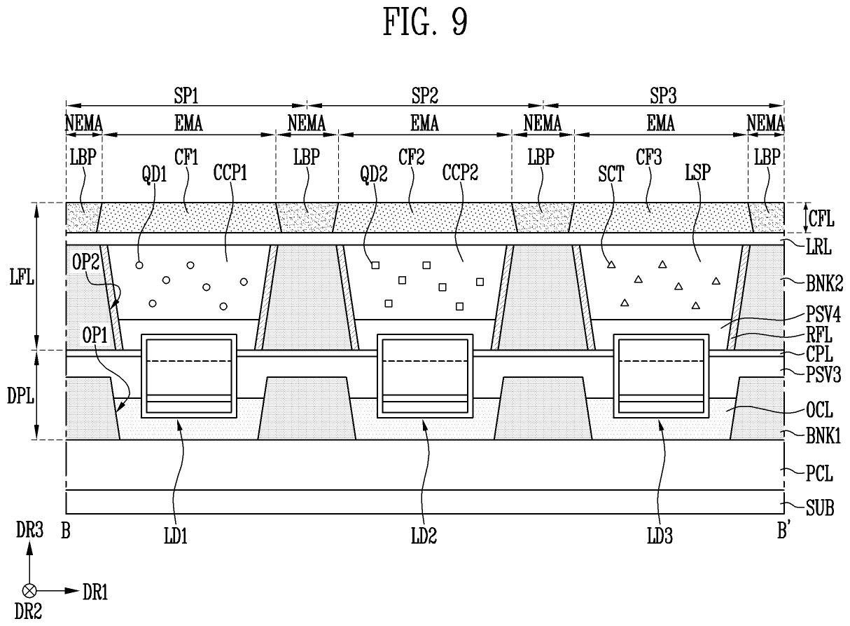

FIG. 9 illustrates a schematic cross-sectional view taken along line B-B′ of FIG. 7.

Referring to FIG. 7 and FIG. 9, the pixel circuit layer PCL, the display element layer DPL, and the light functional layer LFL may be sequentially provided on the substrate SUB.

The pixel circuit layer PCL and the display element layer DPL of FIG. 9 may be similarly configured to those described with reference to FIG. 8. In the pixel circuit layer PCL, sub-pixel circuits corresponding to the first to third sub-pixels SP1 to SP3 may be provided. In the display element layer DPL, the first to third light emitting elements LD1 to LD3 corresponding to the first to third sub-pixels SP1 to SP3, respectively, may be provided. The first to third light emitting elements LD1 to LD3 may overlap the first openings OP1 of the first bank BNK1. The first light emitting element LD1 may be electrically connected between the cathode electrode CE (see FIG. 8) and the transistor T_SP1 (see FIG. 8) included in the sub-pixel circuit of the first sub-pixel SP1. The second light emitting element LD2 may be electrically connected between the cathode electrode CE and the transistor included in the sub-pixel circuit of the second sub-pixel SP2. The third light emitting element LD3 may be electrically connected between the cathode electrode CE and the transistor included in the sub-pixel circuit of the third sub-pixel SP3. Hereinafter, redundant descriptions thereof will be omitted.

The light functional layer LFL may be provided on the display element layer DPL. The light functional layer LFL of FIG. 9 may be similarly configured to that described with reference to FIG. 8. Hereinafter, redundant descriptions thereof will be omitted.

The second bank BNK2 has the second openings OP2. The light emitting area EMA and the non-light emitting area NEMA for the first to third sub-pixels SP1 to SP3 are defined by the second bank BNK2. An area overlapping the second bank BNK2 may correspond to the non-light emitting area NEMA. An area overlapping the second openings OP2 of the second bank BNK2 may correspond to the light emitting area EMA of the first to third sub-pixels SP1 to SP3.

The fourth passivation layer PSV4 may be disposed in the second openings OP2 on the capping layer CPL. On the fourth passivation layer PSV4, first and second light conversion patterns CCP1 and CCP2 and a light scattering pattern LSP may be disposed in the second openings OP2.

The first to third light emitting elements LD1 to LD3 may emit blue-colored light. The first light conversion pattern CCP1 may include first color conversion particles QD1 to convert blue-colored light into red-colored light. The second light conversion pattern CCP2 may include second color conversion particles QD2 to convert blue-colored light into green-colored light. The light scattering pattern LSP may include scattering particles SCT that scatter blue-colored light in order to improve light output efficiency. Accordingly, the first to third sub-pixels SP1 to SP3 may be provided as a red sub-pixel, a green sub-pixel, and a blue sub-pixel, respectively. At least one of the first and second light conversion patterns CCP1 and CCP2 and the light scattering pattern LSP may further include color conversion particles that convert blue-colored light into white-colored light.

The first to third light emitting elements LD1 to LD3 may emit red-colored, green-colored, and blue-colored light, respectively. For example, each of the first and second light conversion patterns CCP1 and CCP2 and the light scattering pattern LSP may include the scattering particles SCT. As described above, the particles included in the first and second light conversion patterns CCP1 and CCP2 and the light scattering pattern LSP may be variously changed according to the first to third light emitting elements LD1 to LD3.

The first and second light conversion patterns CCP1 and CCP2 and the light scattering pattern LSP may be omitted.

The low refractive index layer LRL may be disposed on the second bank BNK2, the reflective layer RFL, the first light conversion pattern CCP1, the second light conversion pattern CCP2, and the light scattering pattern LSP. The low refractive index layer LRL may have a lower refractive index than that of the first and second light conversion patterns CCP1 and CCP2 and the light scattering pattern LSP. The low refractive index layer LRL may be omitted in an area corresponding to the third sub-pixel SP3.

The color filter layer CFL may be disposed on the low refractive index layer LRL. The color filter layer CFL may include first to third color filters CF1 to CF3 and light blocking patterns LBP.

Each of the first to third color filters CF1 to CF3 may selectively transmit light in a desired wavelength range. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter. The first to third color filters CF1 to CF3 may have a higher refractive index than the low refractive index layer LRL. However, embodiments are not limited thereto, and the first to third color filters CF1 to CF3 may have a refractive index lower than or equal to that of the low refractive index layer LRL.

The light blocking patterns LBP may be disposed between the first to third color filters CF1 to CF3 and spaced apart from each other in the first direction DR1. The light emitting area EMA and the non-light emitting area NEMA for the first to third sub-pixels SP1 to SP3 may be defined by the light blocking patterns LBP. An area overlapping the light blocking patterns LBP may correspond to the non-light emitting area NEMA. An area that does not overlap the light blocking patterns LBP may correspond to the light emitting area EMA.

The light blocking patterns LBP may include at least one of various types of light blocking materials. Each of the light blocking patterns LBP may be provided in the form of a multilayer in which at least two of the first to third color filters CF1 to CF3 overlap. For example, each of the light blocking patterns LBP may be formed by overlapping the first to third color filters CF1 to CF3. In another example, among of the light blocking patterns LBP, a light blocking pattern between the first and second color filters CF1 and CF2 may be formed as a multilayer in which the first and second color filters CF1 and CF2 overlap, and among of the light blocking patterns LBP, a light blocking pattern between the second and third color filters CF2 and CF3 may be formed as a multilayer in which the second and third color filters CF2 and CF3 overlap. The light blocking pattern between the first color filter CF1 and the third color filter CF3 of a neighboring pixel may be formed as a multilayer in which the first and third color filters CF1 and CF3 overlap. Each of the first to third color filters CF1 to CF3 may extend to the non-light emitting area NEMA to form the light blocking patterns LBP.

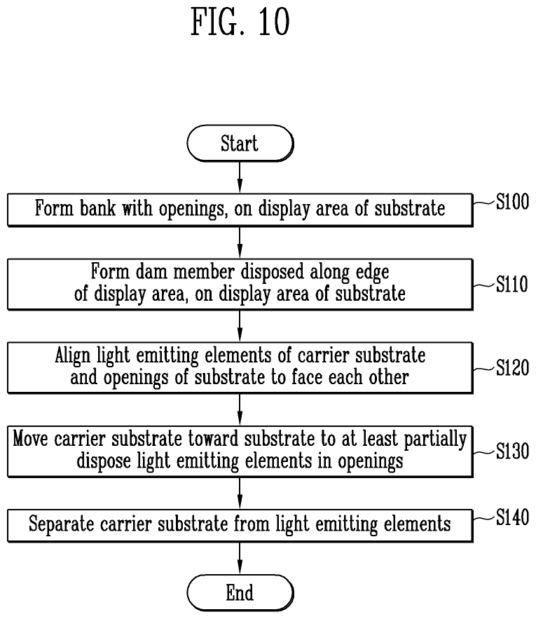

FIG. 10 illustrates a schematic flowchart of a manufacturing method of a display device according to an embodiment.

Referring to FIG. 10, a method of manufacturing the display device DD according to the embodiment may include forming a bank with openings, on a display area of a substrate (S100), forming a dam member (or structure) disposed along an edge of a display area, on the display area of the substrate (S110), aligning light emitting elements of a carrier substrate and the openings of the substrate to face each other (S120), moving the carrier substrate toward the substrate to at least partially dispose the light emitting elements in the openings (S130), and separating the carrier substrate from the light emitting elements (S140).

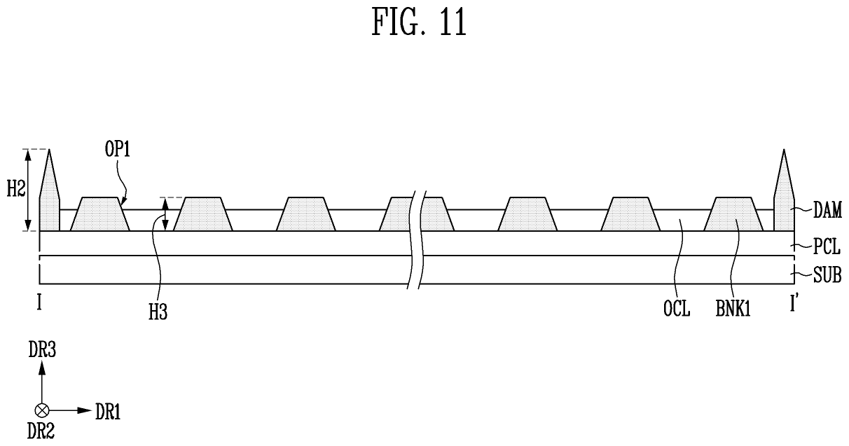

FIG. 11 to FIG. 15 schematically illustrate the method of manufacturing the display device of FIG. 10.

FIG. 11 illustrates a schematic cross-sectional view in S100 and S110 of FIG. 10. Hereinafter, the I-I′ line in each of FIG. 11 to FIG. 15 is a cutting plane line for the same position as the I-I′ line in FIG. 3.

Hereinafter, a method of manufacturing the display device described with reference to FIG. 6 will be described with reference to FIG. 11 to FIG. 15. In the description of FIG. 11 to FIG. 15, descriptions of contents that are already described with reference to FIG. 6 may be omitted.

The pixel circuit layer PCL on the substrate SUB may be formed based on a conventional process for manufacturing a semiconductor device. For example, the conductive layer or insulating layer included in the pixel circuit layer PCL may be formed by a photolithography process. In other examples, the conductive layer or insulating layer included in the pixel circuit layer PCL may be etched by various methods (wet etching, dry etching, or the like), and may be deposited by various methods (sputtering, chemical vapor deposition, or the like). However, embodiments are not limited thereto.

Referring to FIG. 3, FIG. 10, and FIG. 11, in S100, the first bank BNK1 may be formed on the substrate SUB (or the pixel circuit layer PCL).

The first bank BNK1 may be formed by applying an organic material including a light blocking material on the pixel circuit layer PCL and then patterning the same using a mask. The first bank BNK1 may be formed in the third direction DR3 on the display area DA of the substrate SUB extending in the first direction DR1 and the second direction DR2 intersecting the first direction DR1. For example, the first bank BNK1 may have the third height H3 in the third direction DR3.

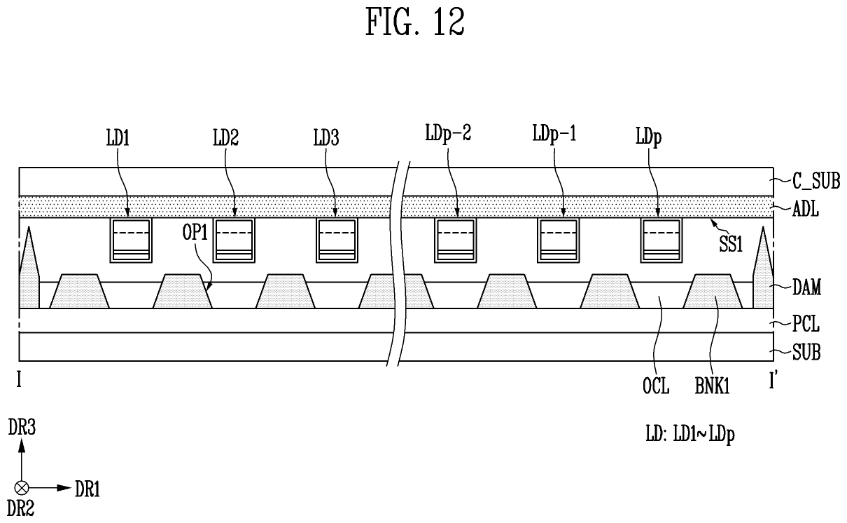

The first bank BNK1 may protrude in the third direction DR3, and may be formed to have the first openings OP1. The overcoat layer OCL may be disposed in the first openings OP1 of the first bank BNK1. Thereafter, the light emitting elements LD (see FIG. 12) may be disposed on the overcoat layer OCL in the first openings OP1, respectively. Thus, the first openings OP1 of the first bank BNK1 may correspond to the light emitting area.

In S110, the dam member DAM may be formed on the substrate SUB (or the pixel circuit layer PCL).

The dam member (or structure) DAM may be formed by patterning the pixel circuit layer PCL using a mask. The dam member DAM may be formed in the third direction DR3 in the display area DA, and may be disposed along the edge of the display area DA. For example, the dam member DAM may have the second height H2 greater than the third height H3 in the third direction DR3.

Although FIG. 11 illustrates that the first bank BNK1 and the dam member DAM are sequentially formed, this disclosure is not limited thereto. For example, the first bank BNK1 and the dam member DAM are formed in the same process, but they may be formed to have different heights. For example, the first bank BNK1 and the dam member DAM may be formed to have different heights through a patterning process using a multi-halftone mask. The multi-halftone mask has slits formed in a partial area, so that the amount of light transmission may vary depending on the area. Due to the difference in the amount of light transmission, the degree of etching may vary for each area. However, embodiments are not limited thereto.

The heights H2 and H3 of the first bank BNK1 and the dam member DAM may be changed by adjusting the amount of light transmission using a mask. For example, the first bank BNK1 may be formed to have a relatively low height by increasing the amount of light transmission. By reducing the amount of light transmission, the dam member DAM may be formed to have a relatively high height. By reducing the amount of light transmission to the edge area of the display area DA of the mask, it is possible to provide a dam member DAM that is relatively higher than the first bank BNK1.

FIG. 12 illustrates a schematic cross-sectional view in S120 of FIG. 10.

Referring to FIG. 3, FIG. 10, and FIG. 12, before S120, the light emitting elements LD may be formed on a carrier substrate C_SUB and one surface SSI of the carrier substrate C_SUB. A method of forming the light emitting elements LD on the carrier substrate C_SUB and one surface SSI of the carrier substrate C_SUB is not limited. For example, various known semiconductor manufacturing methods may be applied.

The carrier substrate C_SUB may be a substrate for forming the light emitting elements LD. For example, the light emitting elements LD may be formed by being grown on a semiconductor substrate such as a silicon wafer. For example, the light emitting elements LD may be similarly configured to the first light emitting element LD1 described with reference to FIG. 8.

Thereafter, the light emitting elements LD may be transferred onto the overcoat layer OCL (or anode electrodes) of the substrate SUB through a stamp method using an elastic polymer material as a transfer substrate. Accordingly, the carrier substrate C_SUB may include an adhesive layer ADL on one surface SS1 of the carrier substrate C_SUB. The adhesive layer ADL may be disposed between the carrier substrate C_SUB and the light emitting elements LD. For example, the adhesive layer ADL may include poly dimethyl siloxane (PDMS), but is not limited thereto.

In S120, the carrier substrate C_SUB and the substrate SUB may be aligned with each other. By moving the carrier substrate C_SUB in the first direction DR1 and/or the second direction DR2, the light emitting elements LD of the carrier substrate C SUB and the first openings OP1 of the substrate SUB may be aligned to face each other in the third direction DR3. The carrier substrate C_SUB may be aligned so that the light emitting elements LD are disposed on the overcoat layer OCL of the substrate SUB.

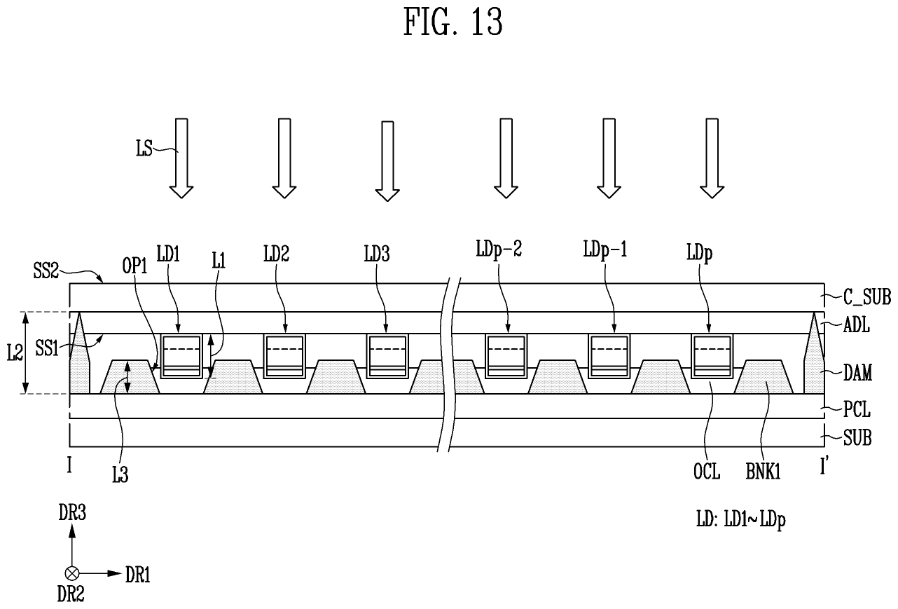

FIG. 13 illustrates a schematic cross-sectional view in S130 of FIG. 10.

Referring to FIG. 3, FIG. 10, and FIG. 13, in S130, by moving the carrier substrate C_SUB toward the substrate SUB, the light emitting elements LD may be at least partially disposed in the first openings OP1. The carrier substrate C_SUB may be moved in a direction opposite to the third direction DR3 toward the substrate SUB, and accordingly, the light emitting elements LD may be partially buried in the overcoat layer OCL disposed in each of the first openings OP1. However, this is an example, and this disclosure is not limited thereto. For example, the overcoat layer OCL is partially provided only in the area adjacent to the lower portion of the light emitting elements LD so that the light emitting elements LD may not be partially buried in the overcoat layer OCL.

Thereafter, heat or pressure may be applied to another surface SS2 opposite to the one surface SS1 of the carrier substrate C_SUB. For example, heat and pressure may be applied by irradiating a laser LS. Accordingly, the light emitting elements LD of the carrier substrate C_SUB may be bonded to the anode electrodes AE1 (see FIG. 8) of the substrate SUB. This may be performed by applying heat and pressure at a certain temperature to the area in which the light emitting elements LD and the anode electrode are in contact with each other. The light emitting elements LD and the anode electrodes may be bonded by a bonding member including an Sn—Ag—Cu (SAC) alloy in an area in which the light emitting elements LD and the anode electrodes are in contact with each other.

The adhesive layer ADL disposed between the carrier substrate C_SUB and the light emitting elements LD may expand depending on heat and pressure. Since the bonding member is melted by heat, the light emitting elements LD cannot be fixed to the substrate SUB and may move radially as the adhesive layer ADL expands. In case that the light emitting elements LD move unexpectedly, the light emitting elements LD and the substrate SUB (or the anode electrodes) will be misaligned. Accordingly, the electrical connection between the light emitting elements LD and the substrate SUB (or the anode electrodes) may become unstable, and the display quality of the display device may be relatively low.

The dam member DAM may protrude toward the carrier substrate C_SUB along the edge of the display area DA. For example, the dam member DAM may protrude in the third direction DR3 by the second length L2 greater than the sum of the first length L1 of the light emitting elements LD and the third length L3 of the first bank BNK1. Accordingly, the dam member DAM may block or at least reduce the expansion of the adhesive layer ADL depending on heat and pressure by penetrating the adhesive layer ADL of the carrier substrate C_SUB during the bonding process, thereby suppressing or preventing unintended movement of the light emitting elements LD.

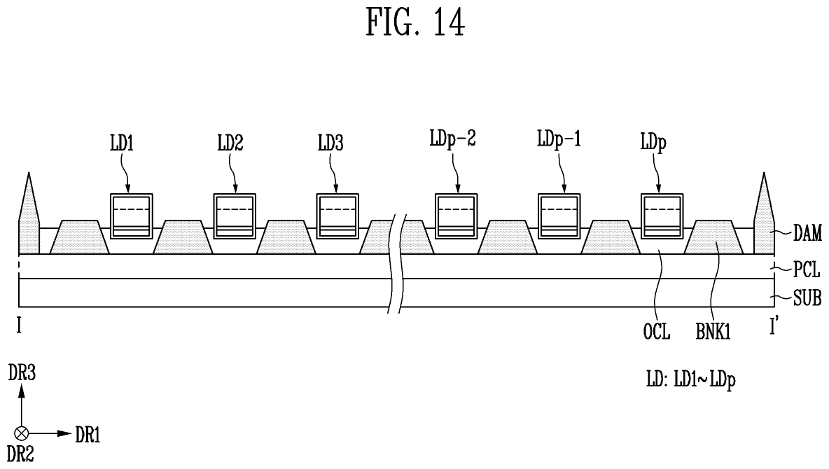

FIG. 14 illustrates a schematic cross-sectional view in S140 of FIG. 10.

Referring to FIG. 3, FIG. 10, and FIG. 14, in S140, the carrier substrate C_SUB may be separated from the light emitting elements LD. The carrier substrate C_SUB may be separated from the light emitting elements LD by moving the carrier substrate C_SUB in a direction away from the substrate SUB. The bonding between the light emitting elements LD and the anode electrodes may be maintained. The adhesion between the light emitting elements LD and the overcoat layer OCL may be maintained. For example, the light emitting elements LD may maintain substantially the same position at which they were attached to the overcoat layer OCL in S130.

The bonding force between the adhesive layer ADL (see FIG. 12) and the light emitting elements LD may be weaker than the adhesion force between the light emitting elements LD and the overcoat layer OCL. Accordingly, the carrier substrate C SUB is separated from the light emitting elements LD, but the adhesion between the light emitting elements LD and the overcoat layer OCL may be maintained.

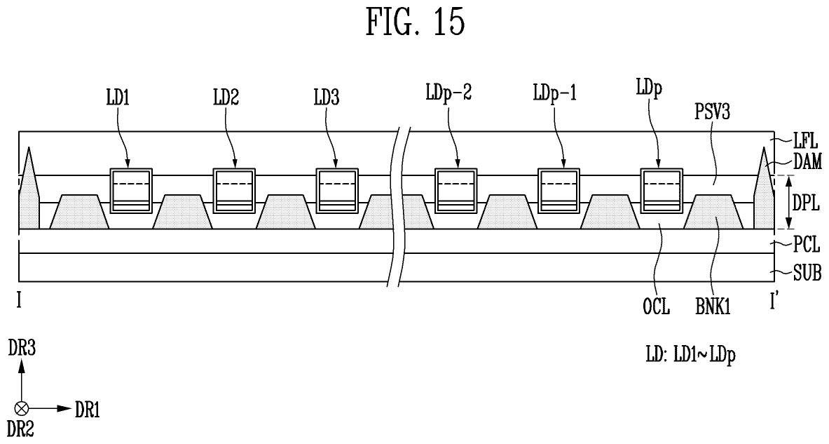

FIG. 15 illustrates a schematic cross-sectional view after S140 of FIG. 10.

Referring to FIG. 3, FIG. 9, FIG. 10, and FIG. 15, the light functional layer LFL may be further formed on the display device layer DPL including the light emitting elements LD after S140. For example, the third passivation layer PSV3 and the capping layer CPL may be further formed. The display panel DP including the substrate SUB, the pixel circuit layer PCL, the display element layer DPL, and the light functional layer LFL may be formed. As the dam member DAM is not separated from the substrate SUB together with the carrier substrate C_SUB, the display element layer DPL may include the overcoat layer OCL, the third passivation layer PSV3, the light emitting elements LD, the first bank BNK1, and the dam member DAM.

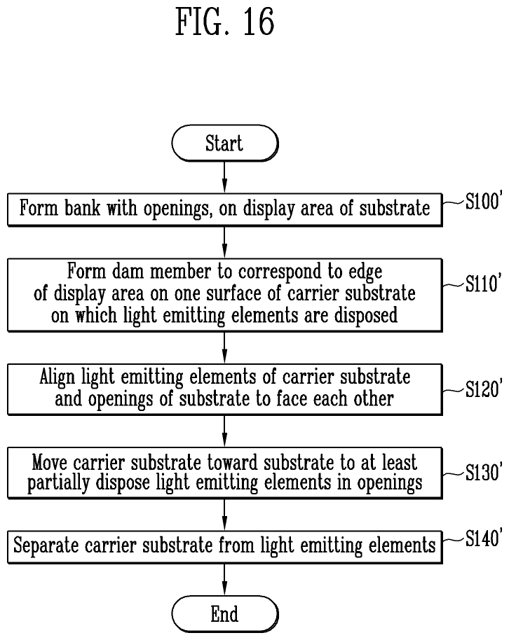

FIG. 16 illustrates a schematic flowchart of a method of manufacturing a display device according to another embodiment of this disclosure.

Referring to FIG. 16, a method of manufacturing the display device DD according to another embodiment may include forming a bank with openings, on a display area of a substrate (S100′), forming a dam member to correspond to an edge of a display area on one surface of a carrier substrate on which light emitting elements are disposed (S110′), aligning the light emitting elements of the carrier substrate and the openings of the substrate so as to face each other (S120′), moving the carrier substrate toward the substrate to at least partially dispose the light emitting elements in the openings (S130′), and separating the carrier substrate from the light emitting elements (S140′).

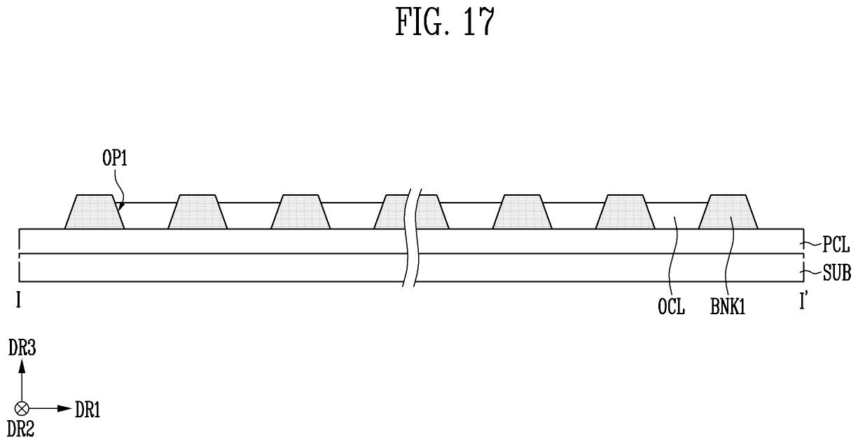

FIG. 17 to FIG. 22 schematically illustrate the method of manufacturing the display device of FIG. 16.

FIG. 17 illustrates a schematic cross-sectional view in S100′ of FIG. 16. Hereinafter, the I-I′ line in each of FIG. 17 to FIG. 22 is understood as a cutting plane line for the same position as the I-I′ line in FIG. 3.

Hereinafter, a method of manufacturing the display device described with reference to FIG. 6 will be described with reference to FIG. 17 to FIG. 22. In the description of FIG. 17 to FIG. 22, descriptions of contents that are already described with reference to FIG. 6 may be omitted.

The pixel circuit layer PCL on the substrate SUB may be formed based on a conventional process for manufacturing a semiconductor device. For example, the conductive layer or the insulating layer included in the pixel circuit layer PCL may be formed by a photolithography process. Alternatively, the conductive layer or insulating layer included in the pixel circuit layer PCL may be etched by various methods (wet etching, dry etching, or the like), and may be deposited by various methods (sputtering, chemical vapor deposition, or the like). However, embodiments are not limited thereto.

Referring to FIG. 3, FIG. 16, and FIG. 17, in S100′, the first bank BNK1 may be formed on the substrate SUB (or the pixel circuit layer PCL). The method of forming the first bank BNK1 having the first openings OP1 on the display area DA of the substrate SUB (or the pixel circuit layer PCL) may be similarly configured to that described with reference to FIG. 11. Hereinafter, descriptions of redundant contents will be omitted. However, the dam member DAM (see FIG. 6) may not be formed on the substrate SUB (or the pixel circuit layer PCL).

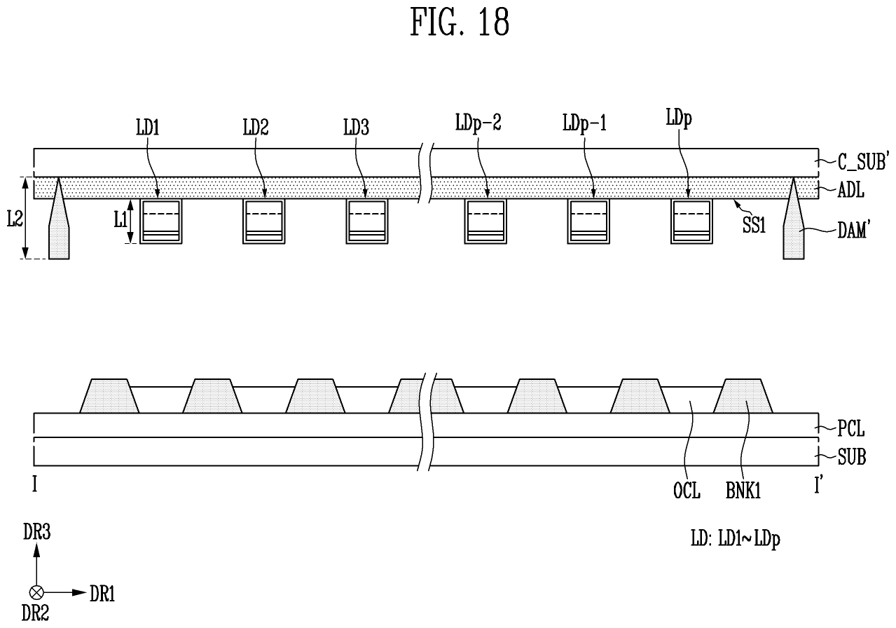

FIG. 18 illustrates a schematic cross-sectional view in S110′ of FIG. 16.

Referring to FIG. 3, FIG. 16, and FIG. 18, in S110′, a dam member DAM′ may be formed on a carrier substrate C_SUB′ and one surface SS1 of the carrier substrate C_SUB′.

The dam member DAM′ may be formed to penetrate the adhesive layer ADL on one surface SS1 of the carrier substrate C_SUB′. For example, the dam member DAM′ may be separately formed and then attached to the adhesive layer ADL. However, it is not limited thereto. For example, the dam member DAM′ may be formed directly on one surface SSI of the carrier substrate C_SUB′. The adhesive layer ADL may not be interposed between the dam member DAM′ and the carrier substrate C_SUB′.

The dam member DAM′ may be formed in a direction opposite to the third direction DR3 from one surface SS1 of the carrier substrate C_SUB′ toward the substrate SUB. The dam member DAM′ may be disposed to correspond to the edge of the display area DA of the substrate SUB. For example, the dam member DAM′ may have the second length L2 longer than the first length L1 of the light emitting elements LD in the third direction DR3. Accordingly, the dam member DAM′ attached to the carrier substrate C_SUB′ may further protrude from the light emitting elements LD in a direction opposite to the third direction DR3.

Accordingly, the dam member DAM′ may block the expansion of the adhesive layer ADL depending on heat and pressure by penetrating the adhesive layer ADL of the carrier substrate C_SUB′ during the bonding process, and may suppress or prevent unintended movement of the light emitting elements LD.

Referring to FIG. 3, FIG. 16, and FIG. 18, the light emitting elements LD may be formed on one surface SS1 of the carrier substrate C_SUB′. The method of forming the carrier substrate C_SUB′ and the light emitting elements LD on the carrier substrate C_SUB′ may be similarly configured to that described with reference to FIG. 12. Hereinafter, descriptions of redundant contents will be omitted.

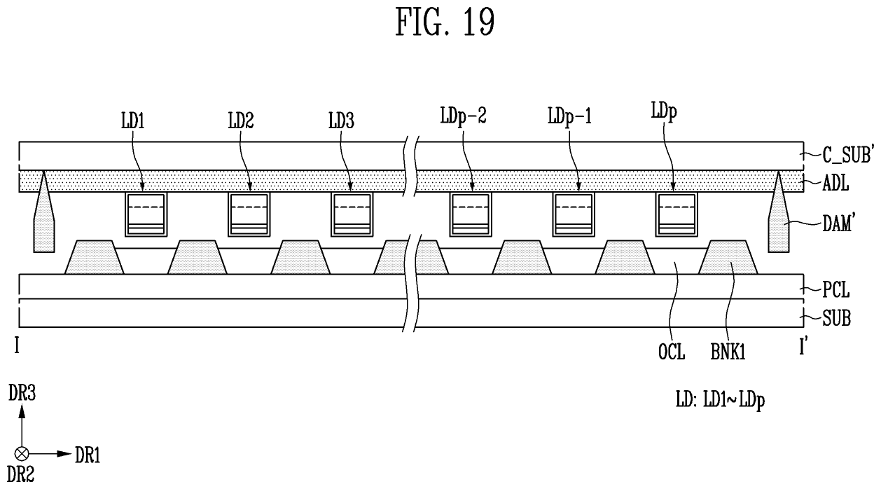

FIG. 19 illustrates a cross-sectional view in S120′ of FIG. 16.

Referring to FIG. 3, FIG. 16, and FIG. 19, in S120′, the carrier substrate C_SUB′ and the substrate SUB may be aligned with each other. That method of aligning the light emitting elements of the carrier substrate and the openings of the substrate to face each other may be configured similarly to that described with reference to FIG. 12. Hereinafter, descriptions of redundant contents will be omitted.

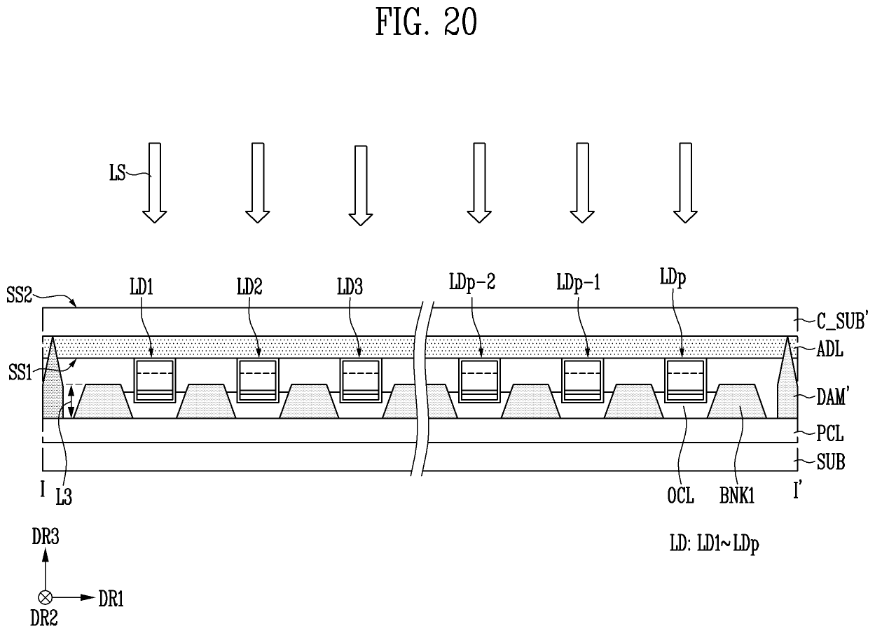

FIG. 20 illustrates a cross-sectional view in S130′ of FIG. 16.

Referring to FIG. 3, FIG. 16, and FIG. 20, in S130′, by moving the carrier substrate C_SUB′ toward the substrate SUB, the light emitting elements LD may be at least partially disposed in the first openings OP1. Thereafter, heat or pressure may be applied to another surface SS2 opposite to the one surface SS1 of the carrier substrate C_SUB′. The step of at least partially disposing the light emitting elements LD of the carrier substrate C_SUB′ in the first openings OP1, and applying heat or pressure may be configured similarly to that described with reference to FIG. 13. Hereinafter, descriptions of redundant contents will be omitted.

The dam member DAM′ may protrude from one surface SS1 of the carrier substrate C_SUB′ toward the substrate SUB along the edge of the display area DA. For example, the dam member DAM′ may protrude in the third direction DR3 reference by the second length L2 (see FIG. 18) greater than the sum of the first length L1 (see FIG. 18) of the light emitting elements LD and the third length L3 of the first bank BNK1.

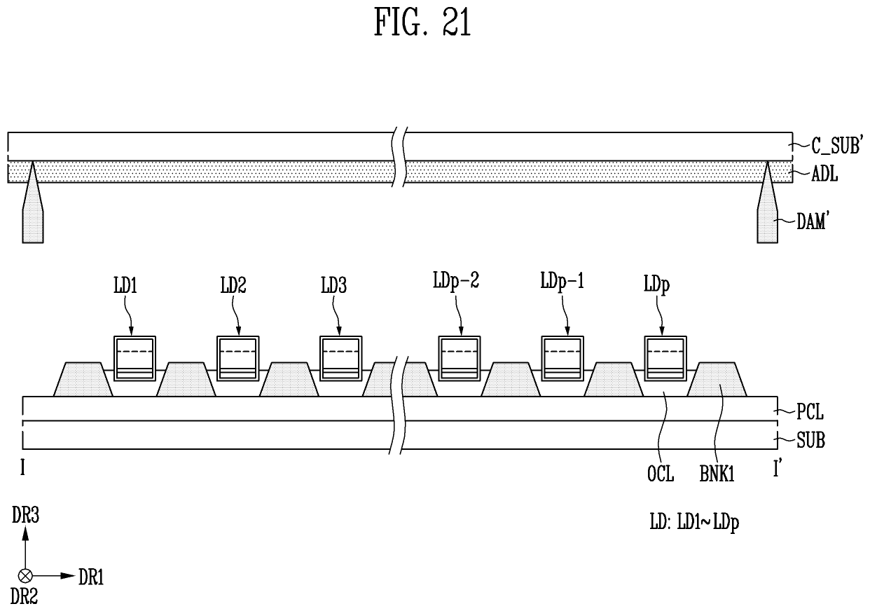

FIG. 21 illustrates a schematic cross-sectional view in S140′ of FIG. 16.

Referring to FIG. 3, FIG. 16, and FIG. 21, in S140′, the carrier substrate C_SUB′ may be separated from the light emitting elements LD by moving it in a direction away from the substrate SUB. The method of separating the carrier substrate C_SUB′ from the light emitting elements LD may be similarly configured to that described with reference to FIG. 14. Hereinafter, descriptions of redundant contents will be omitted. However, the dam member DAM′ may be separated from the substrate SUB together with the carrier substrate C_SUB′. For example, the light emitting elements LD are maintained to be attached to the overcoat layer OCL on the substrate SUB, but the dam member DAM′ may be separated from the substrate SUB.

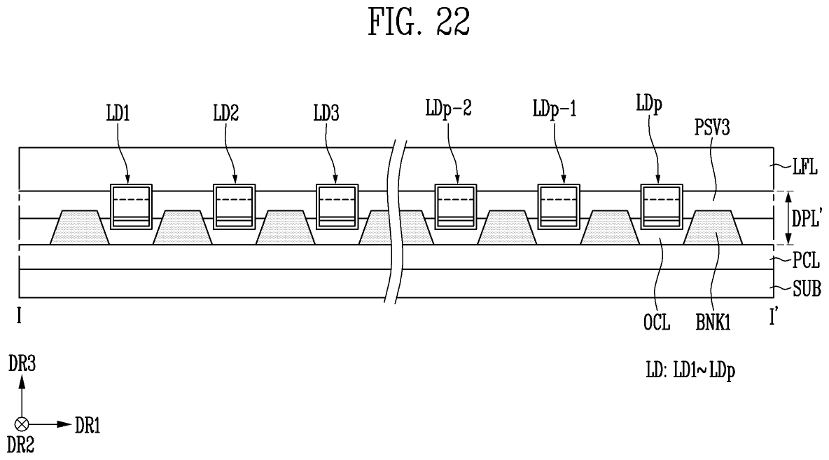

FIG. 22 illustrates a cross-sectional view after S140′ of FIG. 16.

Referring to FIG. 3, FIG. 9, FIG. 16, and FIG. 22, the light functional layer LFL may be further formed on the display device layer DPL including the light emitting elements LD after S140′. The display panel DP including the substrate SUB, the pixel circuit layer PCL, the display element layer DPL′, and the light functional layer LFL may be formed. As the dam member DAM′ is separated from the substrate SUB together with the carrier substrate C_SUB′, the display element layer DPL′ may include the overcoat layer OCL, the third passivation layer PSV3, the light emitting elements LD, and the first bank BNK1, and may not include the dam member DAM′.

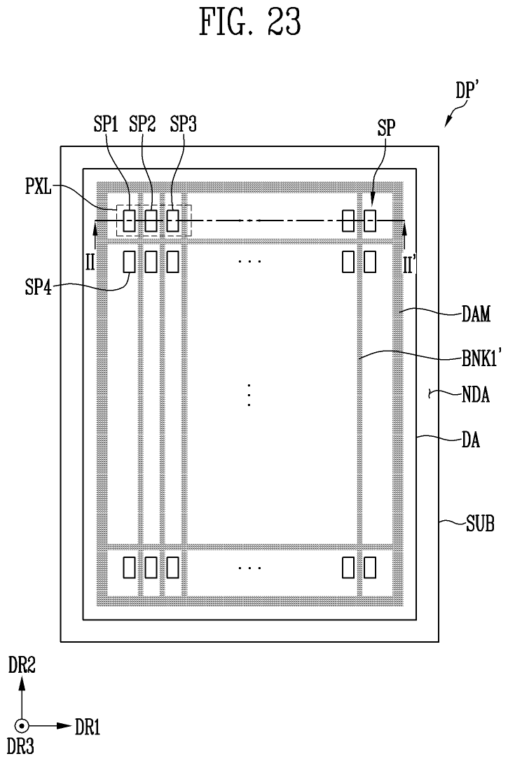

FIG. 23 illustrates a schematic top plan view of a display panel of FIG. 1 according to another embodiment.

Referring to FIG. 23, the display panel DP′ may include the substrate SUB, the display area DA, the non-display area NDA, the pixel PXL, the sub-pixels SP, and the dam member DAM. The substrate SUB, the display area DA, the non-display area NDA, the pixel PXL, the sub-pixels SP, and the dam member DAM may be similarly configured to those described with reference to FIG. 3. Hereinafter, descriptions of redundant contents will be omitted.

The display panel DP′ may include a first bank BNK1′ having substantially the same height as the dam member DAM. The area in which the first bank BNK1′is disposed may be a non-light emitting area. The first bank BNK1′ may be disposed to surround each of the sub-pixels SP in a plan view. The first banks BNK1′ may be disposed to be spaced apart from each other in the first direction DR1 and the second direction DR2 intersecting the first direction DR1 in an area surrounded by the dam member DAM.

The first bank BNK1′ having substantially the same height as the dam member DAM may be disposed between the sub-pixels SP. For example, the first bank BNK1′ may be disposed between the first sub-pixel SP1 and the second sub-pixel SP2, and may extend in the second direction DR2. The first bank BNK1′ may be disposed between the first sub-pixel SP1 and the fourth sub-pixel SP4, and may extend in the first direction DR1.

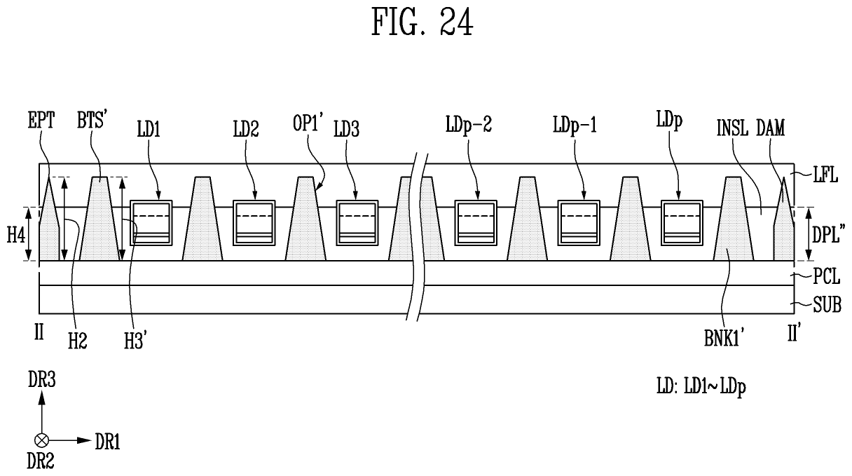

FIG. 24 illustrates a schematic cross-sectional view taken along line II-II′ of FIG. 23.

Referring to FIG. 23 and FIG. 24, the pixel circuit layer PCL, a display element layer DPL″, and the light functional layer LFL may be sequentially disposed in the third direction DR3 on the substrate SUB. The display element layer DPL″ may include the light emitting elements LD, the first bank BNK1, and the dam member DAM. The substrate SUB, the pixel circuit layer PCL, the light functional layer LFL, the light emitting elements LD, and the dam member DAM may be similarly configured to those described with reference to FIG. 6. Hereinafter, descriptions of redundant contents will be omitted.

The first bank BNK1′ may be disposed on the display area DA of the substrate SUB (or the pixel circuit layer PCL) and protrude toward the light functional layer LFL in the third direction DR3. The first bank BNK1′ may have first openings OP1′ corresponding to the light emitting areas of the sub-pixels SP. For example, the first bank BNK1′ may surround the light emitting elements LD disposed in the sub-pixels SP and may have the first openings OP1′ corresponding to the light emitting areas of respective light emitting elements LD.

The dam member DAM may be integrally formed with the first bank BNK1′, but is not limited thereto, and the dam member DAM may be formed separately from the first bank BNK1′.

The dam member DAM may have the second height H2 in the third direction DR3 intersecting the first and second directions DR1 and DR2. The second height H2 may be a distance between the substrate SUB (or the pixel circuit layer PCL) and the end EPT of the dam member DAM. The first bank BNK1′ may have a third height H3′ substantially equal to the second height H2 in the third direction DR3. The third height H3′ may be a distance between the substrate SUB (or the pixel circuit layer PCL) and the upper surface BTS′ of the dam member DAM. The dam member DAM and the first bank BNK1′ may be disposed on the pixel circuit layer PCL to protrude further in the third direction DR3 than the light emitting elements LD.

The display element layer DPL″ may have a fourth height H4 less than the second height H2 of the dam member DAM and the third height H3′ of the first bank BNK1′ in the third direction DR3. Thus, the dam member DAM and the first bank BNK1′ may protrude from the display element layer DPL to the light functional layer LFL.

The dam member DAM and the first bank BNK1′ may be disposed to protrude in a direction opposite to the substrate SUB between the edge of the display area DA and the sub-pixels SP.

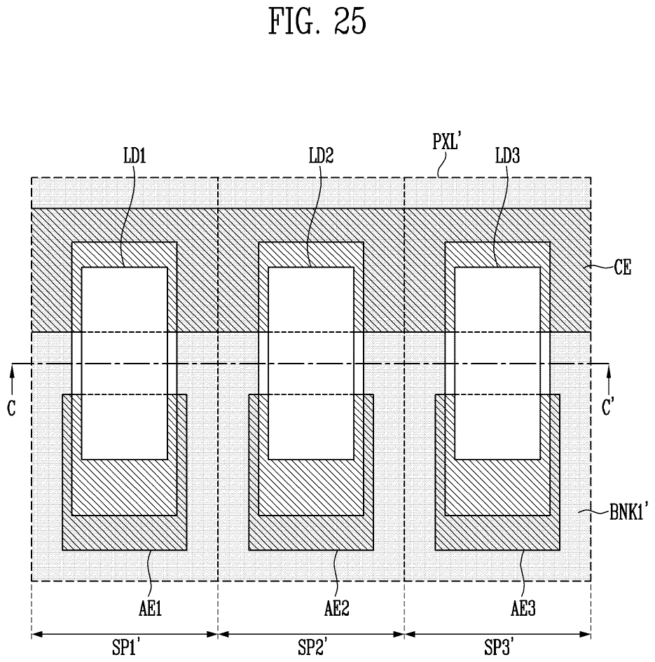

FIG. 25 illustrates a schematic top plan view of one of pixels of FIG. 23 according to an embodiment.

Referring to FIG. 23 and FIG. 25, the pixel PXL′ may include the first to third sub-pixels SP1′ to SP3′. The first to third sub-pixels SP1′ to SP3′ may include first to third anode electrodes AE1 to AE3, a cathode electrode CE, first to third light emitting elements LD1 to LD3, and a first bank BNK1′. The first to third anode electrodes AE1 to AE3, the cathode electrode CE, and the first to third light emitting elements LD1 to LD3 may be similarly configured to those described with reference to FIG. 7. Hereinafter, descriptions of redundant contents will be omitted.

The first bank BNK1′ may be disposed to surround the first to third sub-pixels SP1′ to SP3′. The first bank BNK1′ may be formed between the first to third sub-pixels SP1′ to SP3′ to define a light emitting area. For example, the area in which the first bank BNK1′is disposed may be a non-light emitting area.

The first bank BNK1′ may surround the first to third light emitting elements LD1 to LD3 in a plan view. The first bank BNK1′ may not overlap the first to third light emitting elements LD1 to LD3.

The first bank BNK1′ may be disposed on the first to third anode electrodes AE1 to AE3 and the cathode electrode CE. The first bank BNK1′ may overlap at least some of the first to third anode electrodes AE1 to AE3. The first bank BNK1′ may overlap at least a portion of the cathode electrode CE.

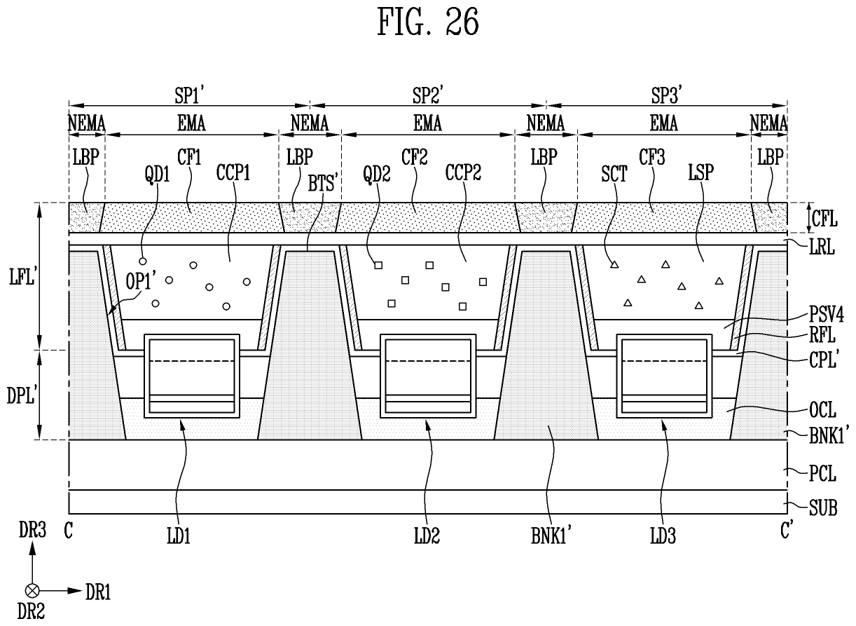

FIG. 26 illustrates a schematic cross-sectional view taken along line C-C′ of FIG. 25.

Referring to FIG. 25 and FIG. 26, the pixel circuit layer PCL, the display element layer DPL′, and the light functional layer LFL′ may be sequentially provided on the substrate SUB. The pixel circuit layer PCL may be similarly configured to that described with reference to FIG. 8.

The display element layer DPL′ may include the first to third light emitting elements LD1 to LD3, the overcoat layer OCL, the third passivation layer PSV3, the first bank BNK1′, and the capping layer CPL′. The first to third light emitting elements LD1 to LD3, the overcoat layer OCL, and the third passivation layer PSV3 may be similarly configured to those described with reference to FIG. 8 and FIG. 9.

The light functional layer LFL′ may include the fourth passivation layer PSV4, the reflective layer RFL, the first and second light conversion patterns CCP1 and CCP2, the light scattering pattern LSP, the low refractive index layer LRL, the color filter layer CFL, the first to third color filters CF1 to CF3, and the light blocking patterns LBP. The fourth passivation layer PSV4, the reflective layer RFL, the first and second light conversion patterns CCP1 and CCP2, the light scattering pattern LSP, the low refractive index layer LRL, the color filter layer CFL, the first to third color filters CF1 to CF3, and the light blocking patterns LBP may be configured similarly to those described with reference to FIG. 8 and FIG. 9. Hereinafter, descriptions of redundant contents will be omitted.

The first bank BNK1′ may have substantially equal height to the dam member DAM (see FIG. 24) in the third direction DR3. The first bank BNK1′ may be disposed on the pixel circuit layer PCL, and may be disposed to at least some of the display element layer DPL′ and the light functional layer LFL′. Accordingly, the first bank BNK1′ may have first openings OP1′ to which the openings of the display element layer DPL′ and the openings of the light functional layer LFL′ are electrically connected.

The capping layer CPL′ may be disposed on the first bank BNK1′. The capping layer CPL′ may be disposed on the upper surface of the first bank BNK1′. The capping layer CPL′ may entirely cover the first bank BNK1′ and the third passivation layer PSV3 except for the light emitting elements LD1 to LD3. In other embodiments, the capping layer CPL′ may not be disposed on the upper surface of the first bank BNK1′.

The fourth passivation layer PSV4 may be disposed in the first bank BNK1′ on the capping layer CPL′. On the fourth passivation layer PSV4, the first and second light conversion patterns CCP1 and CCP2 and a light scattering pattern LSP may be disposed in the first openings OP1′. On the capping layer CPL′, the reflective layer RFL may be disposed on side surfaces of the first bank BNK1′ adjacent to the first openings OP1′.

The first bank BNK1′ may be disposed on the substrate SUB (or the pixel circuit layer PCL) to protrude to at least a portion of the light functional layer LFL′ in the third direction DR3. The first bank BNK1′ is not removed, but is utilized in a subsequent process, thereby improving manufacturing efficiency. For example, the first bank BNK1′ may be used as the second bank BNK2 (see FIG. 9) on the capping layer CPL (see FIG. 9) to prevent light mixing between adjacent sub-pixels.

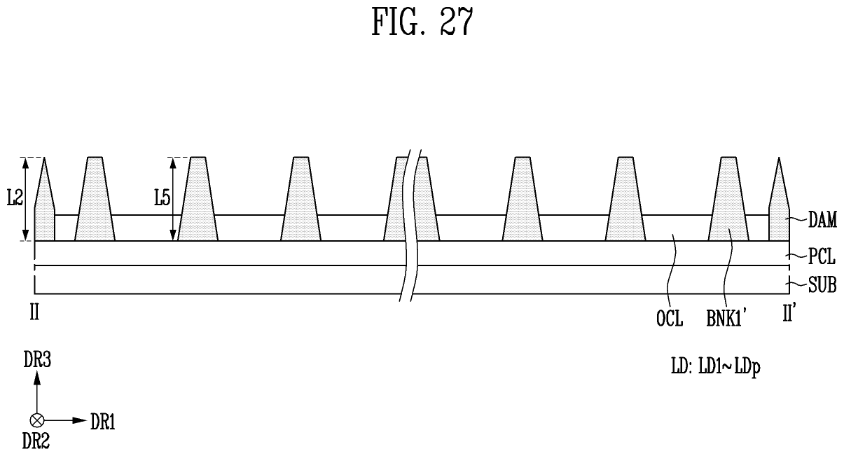

FIG. 27 to FIG. 31 are schematically illustrating a method of manufacturing a display device according to another embodiment of this disclosure.

Hereinafter, the II-II′ line in each of FIG. 27 to FIG. 31 is a cutting plane line for the same position as the II-II′ line in FIG. 23.

Hereinafter, a method of manufacturing the display device described with reference to FIG. 24 will be described with reference to FIG. 27 to FIG. 31. In the description of FIG. 27 to FIG. 31, descriptions of contents that are already described with reference to FIG. 24 may be omitted.

Referring to FIG. 23 and FIG. 27, the dam member (or structure) DAM and the first bank BNK1′ may be formed on the substrate SUB (or the pixel circuit layer PCL). The method of forming the dam member DAM and the first bank BNK1′ on the display area DA of the substrate SUB (or the pixel circuit layer PCL) may be similarly configured to that described with reference to FIG. 11. Hereinafter, descriptions of redundant contents will be omitted.

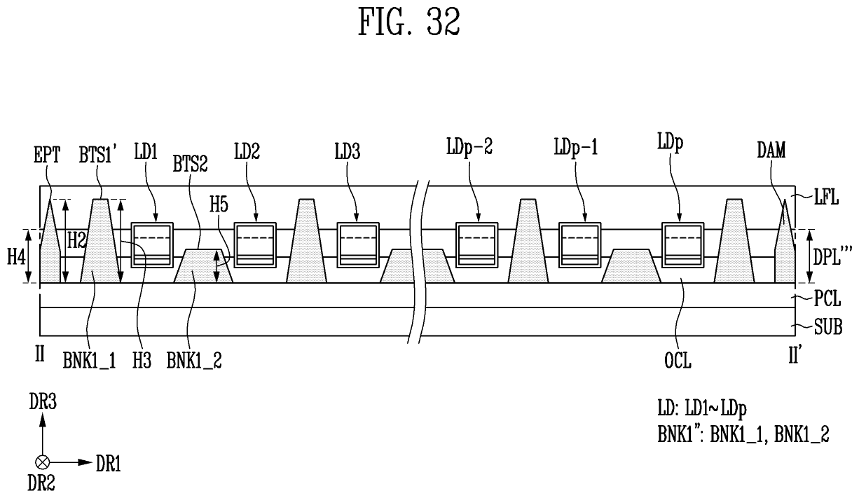

The dam member DAM and the first bank BNK1′ may have substantially equal height. The dam member DAM and the first bank BNK1′ may be formed in the same process to have the same height. For example, the dam member DAM may have a second length L2 in the third direction DR3, and the first bank BNK1′ may have a fifth length L5 substantially equal to the second length L2 in the third direction DR3. In other embodiments, the first bank BNK1′ may have a height that is partially different from a height of the dam member DAM, depending on the position where the first bank BNK1′ is disposed. This will be described later with reference to FIG. 32.

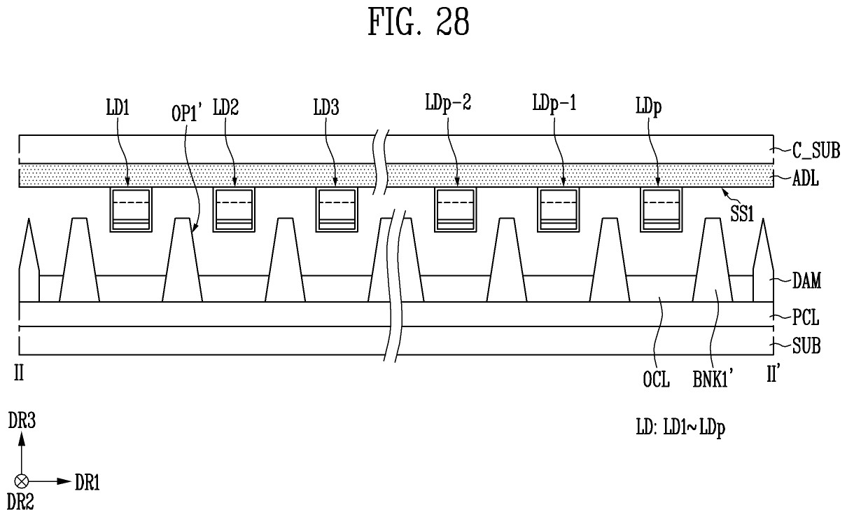

Referring to FIG. 23 and FIG. 28, the light emitting elements LD may be formed on a carrier substrate C_SUB and one surface SS1 of the carrier substrate C_SUB. The method of forming the carrier substrate C_SUB and the light emitting elements LD on one surface SS1 of the carrier substrate C_SUB may be similarly configured to that described with reference to FIG. 12. Hereinafter, descriptions of redundant contents will be omitted.

The carrier substrate C_SUB and the substrate SUB may be aligned with each other. The light emitting elements LD of the carrier substrate C_SUB and the first openings OP1′ of the substrate SUB may be aligned to face each other. The carrier substrate C_SUB may be aligned so that the light emitting elements LD are disposed on the overcoat layer OCL of the substrate SUB. The method for aligning the carrier substrate C_SUB and the substrate SUB may be similarly configured to that described with reference to FIG. 12. Hereinafter, descriptions of redundant contents will be omitted.

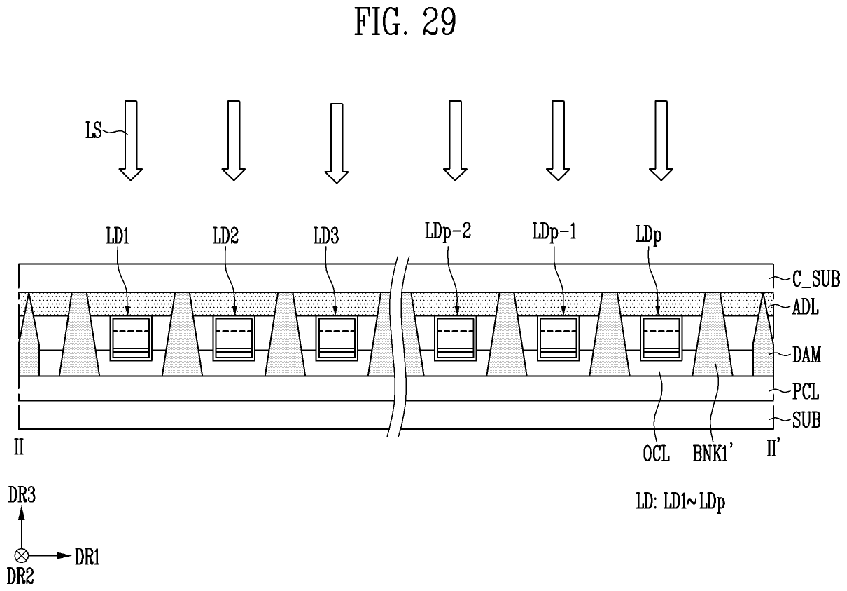

Referring to FIG. 23 and FIG. 29, by moving the carrier substrate C_SUB toward the substrate SUB, the light emitting elements LD may be at least partially disposed in the first openings OP1′. Thereafter, heat or pressure may be applied to another surface SS2 opposite to the one surface SSI of the carrier substrate C_SUB. The step of at least partially disposing the light emitting elements LD of the carrier substrate C_SUB in the first openings OP1′, and applying heat or pressure may be similarly configured to that described with reference to FIG. 13. Hereinafter, descriptions of redundant contents will be omitted.

The dam member DAM and the first bank BNK1′ may protrude toward the carrier substrate C_SUB. The dam member DAM may be disposed along the edge of the display area DA, and the first bank BNK1′ may be disposed between the light emitting elements LD. For example, the dam member DAM and the first bank BNK1′ may protrude from the light emitting elements LD in the third direction DR3 to penetrate the adhesive layer ADL of the carrier substrate C_SUB. For example, like the dam member DAM, the first bank BNK1′ penetrating the adhesive layer ADL of the carrier substrate C_SUB may be disposed between the light emitting elements LD.

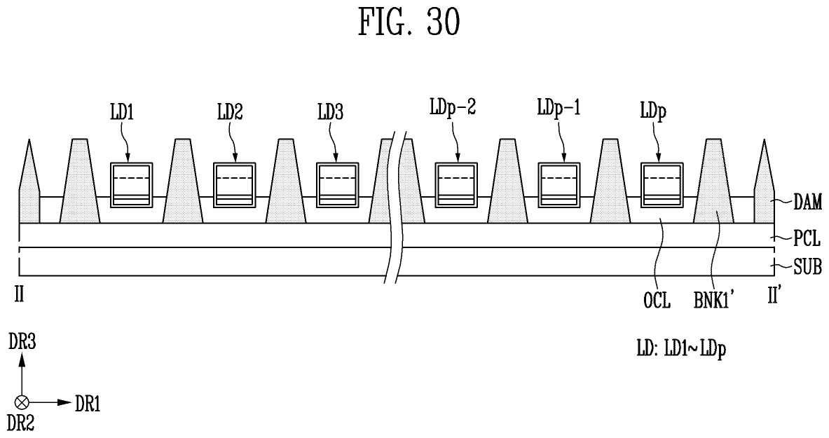

Referring to FIG. 23 and FIG. 30, the carrier substrate C_SUB may be separated from the light emitting elements LD by moving it in a direction away from the substrate SUB. The method of separating the carrier substrate C_SUB from the light emitting elements LD may be configured similarly to that described with reference to FIG. 14. Hereinafter, descriptions of redundant contents will be omitted. The light emitting elements LD may remain attached to the overcoat layer OCL on the substrate SUB, and the dam member DAM and the first bank BNK1′ may also be maintained without being separated from the substrate SUB.

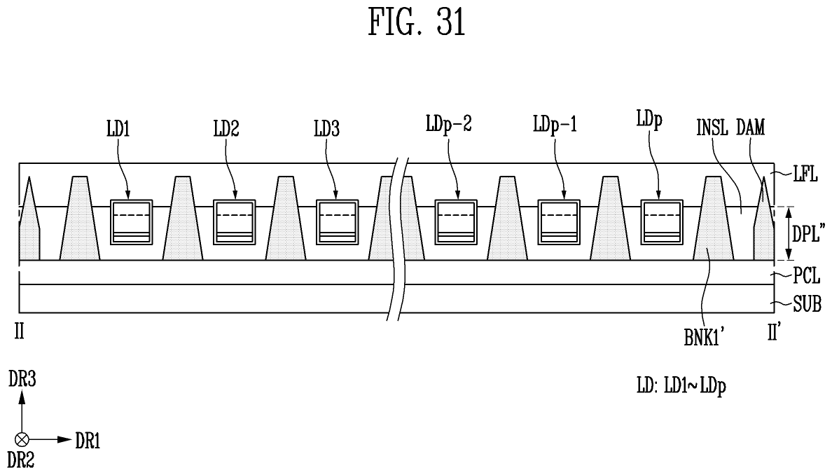

Referring to FIG. 23, FIG. 24, and FIG. 31, the light functional layer LFL may be further formed on the display device layer DPL″ including the light emitting elements LD. The display panel DP including the substrate SUB, the pixel circuit layer PCL, the display element layer DPL″, and the light functional layer LFL may be formed. The dam member DAM and the first bank BNK1′ may be disposed on the pixel circuit layer PCL, and may have a height penetrating at least a portion of the light functional layer LFL.

FIG. 32 illustrates a cross-sectional view taken along line II-II′ of FIG. 23.

Referring to FIG. 23 and FIG. 32, the pixel circuit layer PCL, the display element layer DPL″, and the light functional layer LFL may be sequentially disposed in the third direction DR3 on the substrate SUB. The display element layer DPL″ may include the light emitting elements LD, a first bank BNK1″, and the dam member DAM. The substrate SUB, the pixel circuit layer PCL, the light functional layer LFL, the light emitting elements LD, and the dam member DAM may be similarly configured to those described with reference to FIG. 6. Hereinafter, descriptions of redundant contents will be omitted.

The first bank BNK1″ may include a first portion BNK1_1 and a second portion BNK1_2. For example, in case that the first to p-th light emitting elements LD1 to LDp are arranged in the first direction DR1, a portion of the first portion BNK1_1 of the first bank BNK1″ may be disposed in a direction opposite to the first direction DRI of the first light emitting element LD1. A portion of the second portion BNK1_2 of the first bank BNK1″ may be disposed in the first direction DRI of the first light emitting element LD1. A portion of the second portion BNK1_2 of the first bank BNK1″ may be disposed between the first and second light emitting elements LD1 and LD2. In FIG. 32, it is shown that the first portion BNK1_1 and the second portion BNK1_2 are alternately disposed in the first direction DR1, but this disclosure is not limited thereto. For example, the first portion BNK1_1 and the second portion BNK1_2 may be randomly disposed.

The first portion BNK1_1 may have a third height H3 in the third direction DR3. The third height H3 of the first portion BNK1_1 may be substantially equal to the second height H2 of the dam member DAM. The third height H3 may be a distance between the substrate SUB (or the pixel circuit layer PCL) and the upper surface BTS1′ of the first portion BNK1_1. The second portion BNK1_2 may have a fifth height H5 less than the third height H3 in the third direction DR3. The fifth height H5 may be a distance between the substrate SUB (or the pixel circuit layer PCL) and the upper surface BTS2 of the second portion BNK1 2.

The first portion BNK1_1 of the first bank BNK1″ may have substantially equal height as the dam member DAM, and the second portion BNK1_2 of the first bank BNK1″ may have a height that is less than the dam member DAM. For example, the first bank BNK1″ may have a height that is partially different from that of the dam member DAM, depending on the position where the first bank BNK1″ is disposed. For example, the first bank BNK1″ may be formed to have different heights depending on the position through a patterning process using a multi-halftone mask.

The heights H3 and H5 of the first bank BNK1″ may be changed by adjusting the amount of light transmission using a mask. For example, the second portion BNK1_2 having a relatively low height may be formed in the first bank BNK1″ by increasing the amount of light transmission. The second portion BNK1_1 having a relatively high height may be formed in the first bank BNK1″ by decreasing the amount of light transmission.

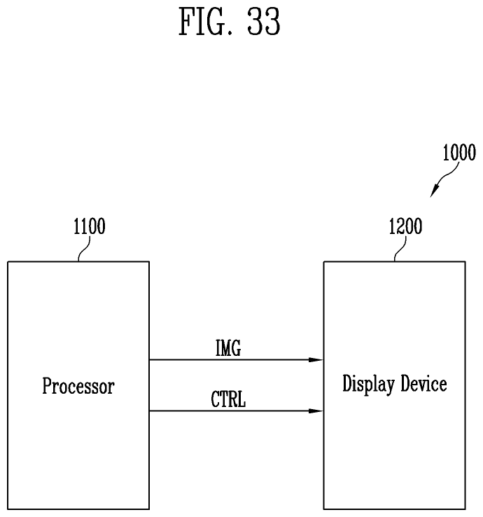

FIG. 33 illustrates a schematic block diagram of a display system according to an embodiment.

Referring to FIG. 33, a display system 1000 may include a processor 1100 and a display device 1200.

The processor 1100 may perform various tasks and calculations. The processor 1100 may include an application processor, a graphics processor, a microprocessor, a central processing unit (CPU), and the like. The processor 1100 may be electrically connected to and step other constituent elements of the display system 1000 through a bus system.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. The image data IMG and the control signal CTRL may be provided as the input image data IMG and the control signal CTRL of FIG. 1, respectively.

The display system 1000 may include a computing system that provides image display functions such as a smart watch, a mobile phone, a smart phone, a portable computer, a tablet personal computer (PC), a watch phone, an automatic display, a smart glass, a portable multimedia layer (PMP), a navigation system, and an ultra mobile personal computer (UMPC). The display system 1000 may include at least one of a head-mounted display device (HMD), a virtual reality (VR) device, a mixed reality (MR) device, and an augmented reality (AR) device.

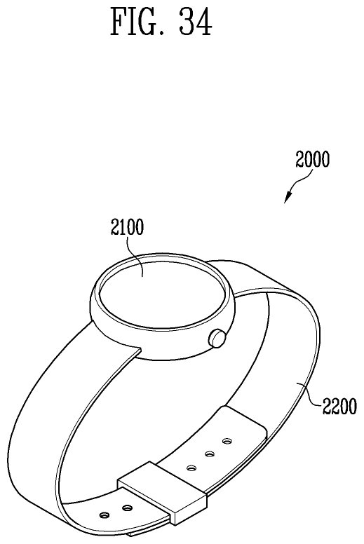

FIG. 34 to FIG. 37 illustrate schematic perspective views of application examples of the display system of FIG. 33.

Referring to FIG. 34, the display system 1000 of FIG. 33 may be applied to a smart watch 2000 including a display portion 2100 and a strap portion 2200.

The smart watch 2000 may be a wearable electronic device. For example, the smart watch 2000 may have a structure in which the strap portion 2200 is mounted on the user's wrist. Here, the display system 1000 and/or the display device 1200 may be applied to the display portion 2100, so that image data including time information may be provided to the user.

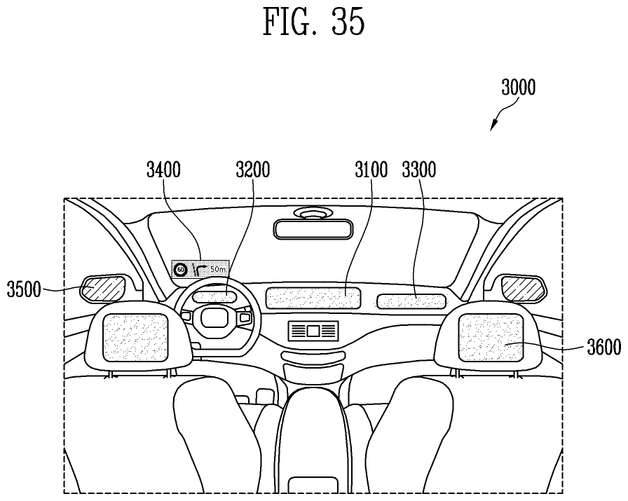

Referring to FIG. 35, the display system 1000 of FIG. 33 may be applied to an automotive display system 3000. Here, the automotive display system 3000 may include a computing system that is provided inside and/or outside the vehicle to provide image data.

For example, the display system 1000 and/or the display device 1200 may be applied to at least one of an infotainment panel 3100, a cluster 3200, a co-driver display 3300, a head-up display 3400, a side mirror display 3500, and a rear-seat display 3600, which are provided in the vehicle.

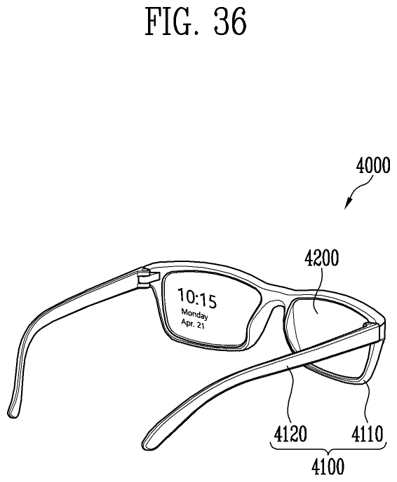

Referring to FIG. 36, the display system 1000 of FIG. 33 may be applied to smart glasses 4000. The smart glasses 4000 may be a wearable electronic device that may be worn on the user's head. For example, the smart glasses 4000 may be a wearable device for augmented reality.

The smart glasses 4000 may include a frame 4100 and a lens portion 4200. The frame 4100 may include a housing 4110 holding the lens portion 4200 and a leg portion 4120 for a user to wear. The leg portion 4120 may be connected to the housing 4110 through a hinge to be folded or unfolded with respect to the housing 4110.

A battery, a touch pad, a microphone, and a camera may be embedded in the frame 4100. A projector that outputs light and a processor that controls an optical signal and the like may be embedded in the frame 4100.

The lens portion 4200 may include an optical member that transmits light or reflects light. For example, the lens portion 4200 may include glass, a transparent synthetic resin, or the like.

In order for the user's eyes to recognize visual information, the lens portion 4200 may reflect an image by an optical signal transmitted from the projector of the frame 4100 by a rear surface of the lens portion 4200 (for example, a surface facing a user's eye). For example, the user may recognize visual information such as time and date displayed on the lens portion 4200. The projector and/or the lens portion 4200 may be a type of display device. The display device 1200 may be applied to the projector and/or the lens portion 4200.

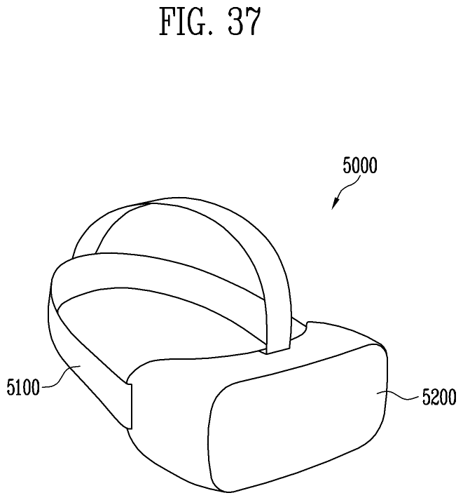

Referring to FIG. 37, the display system 1000 of FIG. 33 may be applied to a head-mounted display device 5000.

The head-mounted display device 5000 may be a wearable electronic device that may be worn on the user's head. For example, the head-mounted display device 5000 may be a wearable device for virtual reality or mixed reality.

The head-mounted display device 5000 may include a head-mounted band 5100 and a display device holding case 5200. The head-mounted band 5100 may be electrically connected to the display device holding case 5200. The head-mounted band 5100 may include a horizontal band and/or a vertical band for fixing the head-mounted display device 5000 to a user's head. The horizontal band may surround the side portion of the user's head, and the vertical band may surround the upper portion of a user's head. However, embodiments are not limited thereto. For example, the head-mounted band 5100 may be implemented in the form of a spectacle frame, a helmet, or the like.

The display device holding case 5200 may accommodate the display system 1000 and/or the display device 1200.

In the display device according to the embodiments of this disclosure, the dam member is disposed on the substrate to penetrate the adhesive layer of the carrier substrate, so that expansion of the adhesive layer ADL due to heat and pressure in the bonding process of light emitting elements may be blocked or at least reduced. Misalignment of the light emitting elements may be prevented by suppressing unintended movement of the light emitting elements due to expansion of the adhesive layer. Accordingly, the display device according to the embodiment of this disclosure may improve display quality by improving the electrical connection reliability of the light emitting elements.

Although certain embodiments and implementations have been described herein, other embodiments and modifications will be apparent from this description. Accordingly, the inventive concept is not limited to the embodiments, but rather to the broader scope of the presented claims and various obvious modifications and equivalent arrangements.

According to the embodiments of this disclosure, a display device with improved reliability and a method of manufacturing the same are provided.

Effects of embodiments of this disclosure are not limited by what is illustrated in the above, and more various effects are included in this specification.

What is claimed is:

1. A display device comprising:
a substrate extending in a first direction and a second direction intersecting the first direction and including a display area and a non-display area around the display area; and
a display element layer disposed on the substrate in a third direction intersecting the first and second directions,
wherein the display element layer includes:
a bank disposed on the display area of the substrate and having openings;
light emitting elements, each of the light emitting elements overlapping the openings and at least partially disposed in the openings; and
a dam member disposed in the display area along an edge of the display area, each of the light emitting elements has a first height in the third direction, and the dam member has a second height greater than the first height in the third direction.

2. The display device of claim 1, wherein
the bank has a third height in the third direction, and
the third height is less than the second height.

3. The display device of claim 1, wherein
the display element layer has a fourth height in the third direction, and
the fourth height is less than the second height.

4. The display device of claim 1, wherein
the first height is a distance between the substrate and an upper surface of a light emitting element, and
the second height is a distance between the substrate and an end of the dam member.

5. The display device of claim 1, wherein
the display element layer further includes anode electrodes which overlap the openings respectively, and
the light emitting elements are disposed on the anode electrodes.

6. The display device of claim 5, further comprising:
bonding members disposed between the light emitting elements and the anode electrodes,
wherein the bonding members include a Sn—Ag—Cu (SAC) alloy.

7. The display device of claim 1, wherein
the display element layer further includes an overcoat layer disposed in the openings, respectively, and
the light emitting elements are partially buried in the overcoat layer.

8. The display device of claim 1, wherein
the bank has a third height in the third direction, and
the third height is substantially equal to the second height.

9. The display device of claim 1, wherein
a first portion of the bank has a third height in the third direction,
a second portion of the bank has a fifth height in the third direction,
the third height is greater than the fifth height, and
the third height is substantially equal to the second height.

10. A method of manufacturing a display device, comprising:
forming, on a display area of a substrate extending in a first direction and a second direction intersecting the first direction, a bank in a third direction intersecting the first and second directions, the bank having openings;
forming a dam member, the dam member disposed along an edge of the display area;
aligning light emitting elements disposed on a surface of a carrier substrate, and the openings to face each other;
moving the carrier substrate toward the substrate and disposing the light emitting elements at least partially in the openings; and
separating the carrier substrate from the light emitting elements.

11. The method of manufacturing the display device of claim 10, wherein the dam member is formed on the substrate in the third direction in the display area.

12. The method of manufacturing the display device of claim 11, wherein
each of the light emitting elements has a first height in the third direction, and
the dam member has a second height greater than the first height in the third direction.

13. The method of manufacturing the display device of claim 12, wherein
the bank has a third height in the third direction, and
the third height is less than or substantially equal to the second height.

14. The method of manufacturing the display device of claim 12, wherein
a first portion of the bank has a third height in the third direction,
a second portion of the bank has a fifth height in the third direction,
the third height is greater than the fifth height, and
the third height is substantially equal to the second height.

15. The method of manufacturing the display device of claim 11, wherein
the disposing of the light emitting elements at least partially in the openings further includes applying heat or pressure to another surface opposite to the surface of the carrier substrate.

16. The method of manufacturing the display device of claim 15, wherein
the carrier substrate includes an adhesive layer disposed on the surface of the carrier substrate,
the adhesive layer is disposed between the carrier substrate and the light emitting elements, and expands by the heat, and
expansion of the adhesive layer is blocked in a portion of the adhesive layer by the dam member.

17. The method of manufacturing the display device of claim 10, wherein the dam member is formed on a surface of a carrier substrate on which light emitting elements are disposed.

18. The method of manufacturing the display device of claim 17, wherein
in the separating of the carrier substrate from the light emitting elements, the dam member is separated from the substrate together with the carrier substrate.

19. The method of manufacturing the display device of claim 17, wherein
each of the light emitting elements has a first length in the third direction, and
the dam member has a second length longer than the first length in the third direction.

20. A display system comprising:
a processor to provide input image data; and
a display device to display an image based on the input image data,
wherein the display device comprises: a substrate extending in a first direction and a second direction intersecting the first direction and including a display area and a non-display area around the display area; and
a display element layer disposed on the substrate in a third direction intersecting the first and second directions,
the display element layer includes:
a bank disposed on the display area of the substrate and having openings;
light emitting elements, each of the light emitting elements overlapping the openings and at least partially disposed in the openings; and
a dam member disposed in the display area along an edge of the display area, each of the light emitting elements has a first height in the third direction, and the dam member has a second height greater than the first height in the third direction.
